(19) United States
(12) Patent Application Publication
(10) Pub. No.: US 2012/0252180 A1
(43) Pub. Date: Oct. 4, 2012

(54) MANUFACTURING METHOD OF SEMICONDUCTOR INTEGRATED CIRCUIT DEVICE

(75) Inventors: Takahiro TOMIMATSU, Kanagawa (JP); Masaru KADOSHIMA, Kanagawa (JP)

(73) Assignee: Renesas Electronics Corporation

(21) Appl. No.: 13/396,359

(22) Filed: Feb. 14, 2012

(30) Foreign Application Priority Data
Mar. 29, 2011 (JP) 2011-072234

(51) Int. Cl. H01L 21/336

(52) U.S. Cl. 438/299; 257/E21.409

(57) ABSTRACT

There is a problem with a CMIS semiconductor integrated circuit using a High-k Gate insulation film that, in a device region having a short channel length and a narrow channel width, with an increase of the film thickness of an Interfacial Layer IL between the High-k Gate insulation film and a silicon-based substrate by activation annealing of source/drain regions, the absolute value of the threshold voltage increases.

One of the inventions of the present application is a manufacturing method of a semiconductor integrated circuit device having a MISFET. The method includes the steps of covering the semiconductor substrate surface with an oxygen absorption film after forming a gate stack of the MISFET and a peripheral structure of the MISFET, performing annealing in that state to activate impurities in the source/drain, and subsequently removing the oxygen absorption film.

### CROSS-REFERENCE TO RELATED APPLICATION

The disclosure of Japanese Patent Application No. 2011-72234 filed on Mar. 29, 2011 including the specification, drawings and abstract is incorporated herein by reference in its entirety.

### BACKGROUND

The present invention relates to a technique which can be effectively applied to a formation technique of a Gate Stack and a peripheral structure in a manufacturing method of a semiconductor integrated circuit device (or a semiconductor device).

US Patent Publication No. 2009-75442 (Patent Document 1) discloses a stress memorization technique (SMT) which uses a metal film as a stress applying film.

US Patent Publication No. 2007-18252 (Patent Document 2) discloses an SMT which uses a silicon nitride film or the like as the stress applying film.

Japanese Patent Laid-Open No. 2004-172389 (Patent Document 3) or U.S. Pat. No. 7,183,204 (Patent Document 4) corresponding to the Japanese Patent discloses an SMT which uses a silicon nitride film, a metal film, a silicide film or the like as the stress applying film.

### SUMMARY

There is a problem with a complementary metal insulator semiconductor (CMIS) semiconductor integrated circuit using a High-k Gate Insulation Layer that, in a device region having a short channel length and a narrow channel width, with an increase of the film thickness of an Interfacial Layer IL between the High-k Gate Insulation Layer and a silicon-based substrate by activation annealing of source/drain regions, the absolute value of the threshold voltage of an N-type MISFET increases, and the absolute value of the threshold voltage of a P-type MISFET decreases, although the degree of change is not as large as that of the N-type MISFET. In addition, there is also a problem that oxygen in an oxide element isolation region or oxygen in a side wall silicon oxide film diffuses in a metal gate electrode, so that the metal gate electrode is oxidized to disturb the work function.

The present invention has been made in view of the above circumstances.

The present invention provides a manufacturing process of a highly reliable semiconductor integrated circuit device.

The other purposes and the new feature of the present invention will become clear from the description of the present specification and the accompanying drawings.

The following explains briefly the outline of a typical invention among the inventions disclosed in the present application.

One of the inventions of the present application is a manufacturing method of a semiconductor integrated circuit device having a metal insulator semiconductor field effect transistor (MISFET), and the method includes the steps of covering the semiconductor substrate surface with an oxygen absorption film after forming a High-k gate stack of and a peripheral structure of the MISFET, performing annealing in that state to activate impurities in the source/drain, and subsequently removing the oxygen absorption film.

The following explains briefly the effect acquired by the typical invention among the inventions disclosed in the present application.

Specifically, the manufacturing method of a semiconductor integrated circuit device having a metal insulator semiconductor field effect transistor (MISFET) covers the semiconductor substrate surface with an oxygen absorption film after forming a High-k gate stack of and the peripheral structure of the MISFET, performs annealing in the above state to activate impurities in the source/drain, and subsequently removes the oxygen absorption film, and then increase of the threshold voltage (the absolute value, to be accurate) of a MISFET having a short channel length and a narrow channel width due to undesired increase of the film thickness of an interfacial silicon oxide film during heat treatment can be controlled.

### BRIEF DESCRIPTION OF THE DRAWINGS

FIG. 1 is a top plan view of a wafer and a semiconductor chip showing a top surface layout of the CMOS chip which is a target device in the manufacturing method of a semiconductor integrated circuit device in accordance with each embodiment of the present application.

FIG. 2 is a schematic top plan view of a wafer and a semiconductor chip showing a relation between a channel direction and a crystal plane orientation over the chip in FIG. 1.

FIG. 3 is a circuit diagram showing a circuit configuration of a logic gate LG over the semiconductor chip in FIG. 1.

FIG. 4 is a circuit diagram showing a circuit configuration of a memory cell MC over the semiconductor chip of FIG. 1.

FIG. 5 is a partial cross-sectional view of a wafer (at the time of completing fabrication of a gate stack) for explaining a CMIS process flow in the manufacturing method of a semiconductor integrated circuit device in accordance with an embodiment of the present application.

FIG. 6 is a partial cross-sectional view of a wafer (at the time of forming an offset spacer silicon nitride film) for explaining the CMIS process flow in the manufacturing method of a semiconductor integrated circuit device in accordance with an embodiment of the present application.

FIG. 7 is a partial cross-sectional view of a wafer (at the time of introducing an N-type source/drain extension region) for explaining the CMIS process flow in the manufacturing method of a semiconductor integrated circuit device in accordance with an embodiment of the present application.

FIG. 8 is a partial cross-sectional view of a wafer (at the time of etching back the offset spacer silicon nitride film) for explaining the CMIS process flow in the manufacturing method of a semiconductor integrated circuit device in accordance with an embodiment of the present application.

FIG. 9 is a partial cross-sectional view of a wafer (at the time of introducing a P-type source/drain extension region) for explaining the CMIS process flow in the manufacturing method of a semiconductor integrated circuit device in accordance with an embodiment of the present application.

FIG. 10 is a partial cross-sectional view of a wafer (at the time of forming a side wall silicon oxide film) for explaining the CMIS process flow in the manufacturing method of a semiconductor integrated circuit device in accordance with an embodiment of the present application.

FIG. 11 is a partial cross-sectional view of a wafer (at the time of forming a side wall silicon nitride film) for explaining the CMIS process flow in the manufacturing method of a semiconductor integrated circuit device in accordance with an embodiment of the present application.

FIG. 12 is a partial cross-sectional view of a wafer (at the time of etching back the side wall insulation film) for explaining the CMIS process flow in the manufacturing method of a semiconductor integrated circuit device in accordance with an embodiment of the present application.

FIG. 13 is a partial cross-sectional view of a wafer (at the time of introducing a P-type high density source/drain region) for explaining the CMIS process flow in the manufacturing method of a semiconductor integrated circuit device in accordance with an embodiment of the present application.

FIG. 14 is a partial cross-sectional view of a wafer (at the time of introducing an N-type high density source/drain region) for explaining the CMIS process flow in the manufacturing method of a semiconductor integrated circuit device in accordance with an embodiment of the present application.

FIG. 15 is a partial cross-sectional view of a wafer (at the time of forming an oxygen absorption film and activation annealing) for explaining the CMIS process flow in the manufacturing method of a semiconductor integrated circuit device in accordance with an embodiment of the present application.

FIG. 16 is a partial cross-sectional view of a wafer (at the time of removing the oxygen absorption film) for explaining the CMIS process flow in the manufacturing method of a semiconductor integrated circuit device in accordance with an embodiment of the present application.

FIG. 17 is a partial cross-sectional view of a wafer (at the time of completing silicidation) for explaining the CMIS process flow in the manufacturing method of a semiconductor integrated circuit device in accordance with an embodiment of the present application.

FIG. 18 is a partial cross-sectional view of a wafer (at the time of forming a CESL) for explaining the CMIS process flow in the manufacturing method of a semiconductor integrated circuit device in accordance with an embodiment of the present application.

FIG. 19 is a partial cross-sectional view of a wafer (at the time of forming a silicon oxide-based premetal insulation film) for explaining the CMIS process flow in the manufacturing method of a semiconductor integrated circuit device in accordance with an embodiment of the present application.

FIG. 20 is a partial cross-sectional view of a wafer (at the time of opening a contact hole) for explaining the CMIS process flow in the manufacturing method of a semiconductor integrated circuit device in accordance with an embodiment of the present application.

FIG. 21 is a partial cross-sectional view of a wafer (at the time of completing the tungsten plug embedding) for explaining the CMIS process flow in the manufacturing method of a semiconductor integrated circuit device in accordance with an embodiment of the present application.

FIG. 22 is a partial cross-sectional view of a wafer (at the time of completing the multilayer wiring) for explaining the CMIS process flow in the manufacturing method of a semiconductor integrated circuit device in accordance with an embodiment of the present application.

FIG. 23 is a partial cross-sectional view of a wafer (at the time of forming an intermediate silicon oxide-based thin film) for explaining a process flow in an exemplary variation of the manufacturing method of a semiconductor integrated circuit device in accordance with an embodiment of the present application.

FIG. 24 is a partial cross-sectional view of a wafer (at the time of forming a silicon nitride-based stressor film and activation annealing) for explaining a process flow in an exemplary variation of the manufacturing method of a semiconductor integrated circuit device in accordance with an embodiment of the present application.

FIG. 25 is a partial cross-sectional view of a wafer (at the time of removing the silicon nitride-based stressor film) for explaining a process flow in an exemplary variation of the manufacturing method of a semiconductor integrated circuit device in accordance with an embodiment of the present application.

FIG. 26 is a partial cross-sectional view of a wafer (at the time of removing the intermediate silicon oxide-based thin film) for explaining a process flow in an exemplary variation of the manufacturing method of a semiconductor integrated circuit device in accordance with an embodiment of the present application.

FIG. 27 is a data plot view showing dependency on channel width of a threshold voltage of a narrow channel width N-channel MISFET having a High-k Gate insulation film and a narrow channel width N-channel MISFET having an SiON gate insulation film.

FIG. 28 is an enlarged top plan view of a device focusing on the N-type MISFETQn (FIG. 3) such as a logic gate LG in FIG. 1 and a periphery of the N-type MISFETQn.

FIG. 29 is an enlarged cross-sectional view of a device corresponding to a section X-X′ in FIG. 28.

FIG. 30 is an enlarged cross-sectional view of a device corresponding to a section Y-Y′ in FIG. 28.

FIG. 31 is a partial cross-sectional view of a wafer (at the time of completing fabrication of the gate stack) for explaining the CMIS process flow in the manufacturing method of a semiconductor integrated circuit device in accordance with the embodiment of Part 2 of the present application.

FIG. 32 is a partial cross-sectional view of a wafer (at time of forming an offset spacer silicon nitride film) for explaining the CMIS process flow in the manufacturing method of a semiconductor integrated circuit device in accordance with the embodiment of Part 2 of the present application.

FIG. 33 is a partial cross-sectional view of a wafer (at the time of introducing an N-type source/drain extension region) for explaining the CMIS process flow in the manufacturing method of a semiconductor integrated circuit device in accordance with the embodiment of Part 2 of the present application.

FIG. 34 is a partial cross-sectional view of a wafer (at the time of etching back the offset spacer silicon nitride film) for explaining the CMIS process flow in the manufacturing method of a semiconductor integrated circuit device in accordance with the embodiment of Part 2 of the present application.

FIG. 35 is a partial cross-sectional view of a wafer (at the time of introducing a P-type source/drain extension region) for explaining the CMIS process flow in the manufacturing method of a semiconductor integrated circuit device in accordance with the embodiment of Part 2 of the present application.

FIG. 36 is a partial cross-sectional view of a wafer (at the time of forming a side wall silicon oxide film) for explaining the CMIS process flow in the manufacturing method of a semiconductor integrated circuit device in accordance with the embodiment of Part 2 of the present application.

FIG. 37 is a partial cross-sectional view of a wafer (at the time of forming a side wall silicon nitride film) for explaining the CMIS process flow in the manufacturing method of a semiconductor integrated circuit device in accordance with the embodiment of Part 2 of the present application.

FIG. 38 is a partial cross-sectional view of a wafer (at the time of etching back the side wall insulation film) for explaining the CMIS process flow in the manufacturing method of a semiconductor integrated circuit device in accordance with the embodiment of Part 2 of the present application.

FIG. 39 is a partial cross-sectional view of a wafer (at the time of introducing a P-type high density source/drain region) for explaining the CMIS process flow in the manufacturing method of a semiconductor integrated circuit device in accordance with the embodiment of Part 2 of the present application.

FIG. 40 is a partial cross-sectional view of a wafer (at the time of introducing an N-type high density source/drain region) for explaining the CMIS process flow in the manufacturing method of a semiconductor integrated circuit device in accordance with the embodiment of Part 2 of the present application.

FIG. 41 is a partial cross-sectional view of a wafer (at the time of forming an oxygen absorption film and activation annealing) for explaining the CMIS process flow in the manufacturing method of a semiconductor integrated circuit device in accordance with the embodiment of Part 2 of the present application.

FIG. 42 is a partial cross-sectional view of a wafer (at the time of removing the oxygen absorption film) for explaining the CMIS process flow in the manufacturing method of a semiconductor integrated circuit device in accordance with the embodiment of Part 2 of the present application.

FIG. 43 is a partial cross-sectional view of a wafer (at the time of completing the silicidation) for explaining the CMIS process flow in the manufacturing method of a semiconductor integrated circuit device in accordance with the embodiment of Part 2 of the present application.

FIG. 44 is a partial cross-sectional view of a wafer (at the time of forming a CESL) for explaining the CMIS process flow in the manufacturing method of a semiconductor integrated circuit device in accordance with the embodiment of Part 2 of the present application.

FIG. 45 is a partial cross-sectional view of a wafer (at the time of forming a silicon oxide-based premetal insulation film) for explaining the CMIS process flow in the manufacturing method of a semiconductor integrated circuit device of the embodiment of Part 2 of the present application.

FIG. 46 is a partial cross-sectional view of a wafer (at the time of completing a surface planarization process before removing a dummy gate electrode) for explaining the CMIS process flow in the manufacturing method of a semiconductor integrated circuit device in accordance with the embodiment of Part 2 of the present application.

FIG. 47 is a partial cross-sectional view of a wafer (at the time of completing a dummy gate electrode removal process) for explaining the CMIS process flow in the manufacturing method of a semiconductor integrated circuit device in accordance with the embodiment of Part 2 of the present application.

FIG. 48 is a partial cross-sectional view of a wafer (at the time of completing an NMIS work function metal film formation process) for explaining the CMIS process flow in the manufacturing method of a semiconductor integrated circuit device in accordance with the embodiment of Part 2 of the present application.

FIG. 49 is a partial-cross sectional view of a wafer (at the time of completing a resist film patterning process for removing an NMIS work function metal film) for explaining the CMIS process flow in the manufacturing method of a semiconductor integrated circuit device in accordance with the embodiment of Part 2 of the present application.

FIG. 50 is a partial cross-sectional view of a wafer (at the time of completing an NMIS work function metal film patterning process) for explaining the CMIS process flow in the manufacturing method of a semiconductor integrated circuit device in accordance with the embodiment of Part 2 of the present application.

FIG. 51 is a partial cross-sectional view of a wafer (at the time of completing a PMIS work function metal film formation and gate electrode embedding groove filling metal film formation process) for explaining the CMIS process flow in the manufacturing method of a semiconductor integrated circuit device in accordance with the embodiment of Part 2 of the present application.

FIG. 52 is a partial cross-sectional view of a wafer (at the time of completing a work function metal CMP process) for explaining the CMIS process flow in the manufacturing method of a semiconductor integrated circuit device in accordance with the embodiment of Part 2 of the present application.

FIG. 53 is a partial cross-sectional view of a wafer (at the time of completing contact hole formation) for explaining the CMIS process flow in the manufacturing method of a semiconductor integrated circuit device in accordance with the embodiment of Part 2 of the present application.

FIG. 54 is a partial cross-sectional view of a wafer (at the time of completing the tungsten plug embedding) for explaining the CMIS process flow in the manufacturing method of a semiconductor integrated circuit device in accordance with the embodiment of Part 2 of the present application.

FIG. 55 is a partial cross-sectional view of a wafer (at the time of completing the multilayer wiring) for explaining the CMIS process flow in the manufacturing method of a semiconductor integrated circuit device in accordance with the embodiment of Part 2 of the present application.

FIG. 56 is a partial cross-sectional view of a wafer (at the time of forming an intermediate silicon oxide-based thin film) for explaining a process flow in an exemplary variation of a manufacturing method of a semiconductor integrated circuit device in accordance with an embodiment of the present application.

FIG. 57 is a partial cross-sectional view of a wafer (at the time of forming a silicon nitride-based stressor film and activation annealing) for explaining a process flow in an exemplary variation of the manufacturing method of a semiconductor integrated circuit device in accordance with an embodiment of the present application.

FIG. 58 is a partial cross-sectional view of a wafer (at the time of removing the silicon nitride-based stressor film) for explaining a process flow in an exemplary variation of the manufacturing method of a semiconductor integrated circuit device in accordance with an embodiment of the present application.

FIG. 59 is a partial cross-sectional view of a wafer (at the time of removing the intermediate silicon oxide-based thin film) for explaining a process flow in an exemplary variation of the manufacturing method of a semiconductor integrated circuit device in accordance with an embodiment of the present application.

### DETAILED DESCRIPTION

### Outline of Embodiments

Representative embodiments of the invention disclosed in the present application will be first outlined below.

1. A manufacturing method of a semiconductor integrated circuit device includes the steps of (a) patterning an active region by forming an oxide element isolation region over a first main surface of a semiconductor wafer; (b) patterning a High-k gate stack of an N-channel MISFET across the active region over the first main surface of the semiconductor wafer; (c) forming a gate side surface structure on the side surface of the patterned gate stack to form a gate structure including the gate stack and the gate side surface structure; (d) forming an impurity-doped region to be source/drain regions of the N-channel MISFET by ion implantation in a semiconductor surface of the active region of the semiconductor wafer on both sides of the gate structure; (e) after the step (d), forming an oxygen absorption film over the first main surface of the semiconductor wafer to cover over the gate structure, over the oxide element isolation region, and over the semiconductor surface; (f) performing activation annealing on the impurity-doped region in a state that the oxygen absorption film covers over the gate structure, over the oxide element isolation region, and over the semiconductor surface; and (g) after the step (f), removing the oxygen absorption film.

2. In the manufacturing method of a semiconductor integrated circuit device of the article 1, the oxygen absorption film is a polysilicon or an amorphous silicon film.

3. In the manufacturing method of a semiconductor integrated circuit device of the article 1 or 2, the semiconductor integrated circuit device is of CMIS type, and the oxygen absorption film does not cover over a P-type MISFET region in the step (f).

4. In the manufacturing method of a semiconductor integrated circuit device of the article 1 or 3, the oxygen absorption film is an amorphous or a poly-SiGe film.

5. In the manufacturing method of a semiconductor integrated circuit device of any one of the articles 1 to 4, lanthanum is added in the High-k Gate insulation film constituting the gate stack.

6. In the manufacturing method of a semiconductor integrated circuit device of any one of the articles 1 to 5, the gate stack is an actual gate stack.

7. In the manufacturing method of a semiconductor integrated circuit device of any one of the articles 1 to 5, the gate stack is a dummy gate stack.

8. The manufacturing method of a semiconductor integrated circuit device of any one of the articles 1 to 7 further includes the steps of (h) after the step (e) and before the step (f) forming a stress applying film, over the oxygen absorption film, to cover above the gate structure, the oxide element isolation region, and the semiconductor surface; and (i) after the step (f) and before the step (g), removing the stress applying film.

9. In the manufacturing method of a semiconductor integrated circuit device of the article 8, the stress applying film is a silicon nitride-based insulation film.

10. The manufacturing method of a semiconductor integrated circuit device of the article 9 further includes the steps of (j) after the step (e) and before the step (h), forming a first silicon oxide-based insulation film on almost entire surface over the oxygen absorption film; and (k) after the step (i) and before the step (g), removing the silicon oxide-based insulation film.

11. In the manufacturing method of a semiconductor integrated circuit device of the article 10, the first silicon oxide-based insulation film is thinner than both the oxygen absorption film and the stress applying film.

12. In the manufacturing method of a semiconductor integrated circuit device of any one of the articles 1 to 11, a second silicon oxide-based insulation film is interposed between the semiconductor surface and the oxygen absorption film in the formation of the oxygen absorption film in the step (e).

[Explanation of Description Form, Basic Terminology, and Usage in the Present Application]

1. The following embodiments will be explained, divided into plural sections or embodiments, if necessary for convenience. Except for the case where it shows clearly in particular, they are not mutually unrelated and one has relationships such as a modification, details, and supplementary explanation of some or entire of another. Additionally, repetitive description of similar parts is omitted in principle. Furthermore, respective components in the embodiments are not indispensable unless explicitly stated otherwise, theoretically limited to the number, or obviously being the contrary from the context.

Furthermore, the terms “semiconductor device” or “semiconductor integrated circuit device” mentioned in the present application mainly refer to units of various transistors (active elements) as well as surrounding resistors, capacitors integrated over a semiconductor chip (such as a single crystal silicon substrate). Here, a metal insulator semiconductor field effect transistor (MISFET) represented by a metal oxide semiconductor field effect transistor (MOSFET) can be given as a representative example of the various transistors. At that time, a complementary metal insulator semiconductor (CMIS) integrated circuit represented by a complementary metal oxide semiconductor integrated (CMOS) circuit, which is a combination of an N-channel MISFET and a P-channel MISFET can be given as a representative example of the integrated circuit configuration.

Wafer processing of recent semiconductor integrated circuit devices (large scale integration (LSI)) can be roughly divided into a front-end-of-line (FEOL) process usually ranging from introduction of a silicon wafer as the raw material to a premetal process (a process including formation of an interlayer insulation film between the lower end of the M1 wiring layer and the gate electrode structure, formation of a contact hole, and embedding of a tungsten plug), and a back-end-of-line (BEOL) process ranging from formation of the M1 wiring layer to formation of a pad opening to a final passivation film over an aluminum-based pad electrode (the process is included in a wafer level package process). In the FEOL process, gate electrode patterning and contact hole formation are microfabrication processes which require particularly minute fabrication. On the other hand, the BEOL process particularly requires microfabrication in the process of forming vias and trenches, especially for local wiring in relatively lower layers (a minute embedded wiring ranging from M1 to M3 in a four-layer embedded wiring, or from M1 to M5 in a ten-layer embedded wiring). “MN” (usually N=1 to 15) expresses the N-th layer wiring in the order from the bottom. M1 is the first layer wiring and M3 is the third layer wiring.

2. Similarly, in the description of the embodiments, the expression “X comprising A” with regard to materials or components does not exclude an element other than A from being one of the main components unless explicitly stated otherwise or obviously being the contrary from the context. As for a component, it means “X including A as the main component”. A “silicon member” is not limited to pure silicon but may include a member containing SiGe alloy or other multi metal alloy having silicon as the main component, and other additives. Similarly, “silicon oxide film”, “silicon oxide-based insulation film” or the like includes not only relatively pure undoped silicon dioxide but also thermal oxidization film such as fluorosilicate glass (FSG), TEOS-based silicon oxide, silicon oxicarbide (SiOC) or Carbon-doped Silicon oxide or organosilicate glass (OSG), phosphorus silicate glass (PSG), or borophosphosilicate glass (BPSG), coating-based silicon oxide such as a CVD oxidation film, spin on glass (SOG), or Nano-Clustering Silica (NCS), silica-based Low-k insulation films (porous-based insulation films) having empty holes introduced into a member similar to those mentioned above, and composite films with other silicon-based insulation films having these as the main component.

In addition, a silicon nitride-based insulation film is the silicon-based insulation film regularly used for a semiconductor, as well as a silicon oxide-based insulation film. Included in materials belonging to this series are SiN, SiCN, SiNH, and SiCNH. “silicon nitride” includes both SiN and SiNH, unless explicitly stated otherwise. Similarly, “SiCN” includes both SiCN and SiCNH unless explicitly stated otherwise.

Although SiC has a property similar to SiN, SiON should be classified as a silicon oxide-based insulation film in many cases.

Silicon nitride films are frequently used as an etch stop film or a contact etch stop layer (CSEL) in the self-aligned contact (SAC) technique, and also used as stress applying films (stressor or stressor films) in the stress memorization technique (SMT).

Similarly, although “nickel silicide” usually refers to nickel mono-silicide, alloys or mixed crystals having nickel mono-silicide as well as components that are relatively pure are included as the main component. In addition, silicide is not limited to nickel silicide and may be cobalt silicide, titanium silicide, tungsten silicide or the like which have been conventionally used. Besides Ni (nickel) films, nickel alloy films such as a Ni—Pt alloy film (alloy film of Ni and Pt), a Ni—V alloy film (alloy film of Ni and V), a Ni—Pd alloy film (alloy film of Ni and Pd), a Ni—Yb alloy film (alloy film of Ni and Yb), or a Ni—Er alloy film (alloy film of Ni and Er) may be used as a metal film for silicidation. Such silicides having nickel as the main metal element are collectively referred to as “nickel-based silicide”.

3. Although preferred examples are illustrated with regard to figures, positions, attributes or the like, the invention is not strictly limited to them unless explicitly stated otherwise or obviously being the contrary from the context.

4. Furthermore, even if a particular numerical value or quantity is mentioned, the numerical value may be exceeded or the numerical value may not be reached, unless explicitly stated otherwise, theoretically limited to the number, or obviously being the contrary from the context.

5. Although a “wafer” usually refers to a single crystal silicon wafer over which a semiconductor integrated circuit device (similarly, a semiconductor device or an electronic device) will be formed, a composite wafer of an insulation substrate, such as an epitaxial wafer, an SOI substrate or an LCD glass substrate, and a semiconductor layer is also included.

6. In the present application, the term “gate” includes, in addition to an “actual gate” which actually works as a gate (a “dummy gate” or “replacement gate”) which will be removed later. A “gate stack” refers to a stacked body mainly including a gate insulation film and a gate electrode (referred to as an “actual gate stack” when it is particularly necessary to distinguish from a “dummy gate stack”). A “High-k gate stack” refers to a stack having a High-k gate insulation film in the gate insulation film.

In addition, a “gate side surface structure” refers to a gate peripheral structure, such as an offset spacer or a sidewall spacer formed on the side wall of the gate stack. Furthermore, the gate peripheral structure including the gate stack and the gate side surface structure is referred to as a “gate structure”.

Additionally, the “Gate-First approach” in the present application refers to an approach which forms the actual gate stack before activation heat treatment of the source/drain in the manufacturing method of an integrated circuit device having integrated MISFETs in. On the other hand, the “gate-Last approach” refers to an approach which forms the main elements of the actual gate stack after activation heat treatment of the source/drain. One of the gate-last approaches is referred to as a “High-k First/Metal Gate Last approach” in which formation of the interfacial gate insulation film (interface actual gate insulation film) and the High-k Gate insulation film (actual gate insulation film) is performed before activation heat treatment of the source/drain, and formation of the main elements of the actual gate stack in an upper layer is performed after activation heat treatment of the source/drain.

In the High-k First/Metal Gate Last approach, since the interfacial gate insulation film (IL) and the High-k Gate insulation film are elements constituting a dummy gate stack and also constituting an actual gate stack, a naming suited to the context may be used for explaining a process.

Furthermore, an “oxygen absorption film” in the present application refers to a film having a property of absorbing oxygen such as a film having silicon as the main component (an Si-based semiconductor film) such as a polysilicon film, an amorphous silicon film, and a SiGe film. Although a silicon oxide-based insulation film and a silicon nitride-based insulation film are not an oxygen absorption film, a film having apart of the Si-based semiconductor film including a silicon oxide-based insulation film or a silicon nitride-based insulation film (the main part being an Si-based semiconductor film) is an oxygen absorption film as a whole.

The term “crystal plane” or “crystal orientation” does not only refer to a specific crystal plane or crystal orientation but also includes the periphery around the specific crystal plane or crystal orientation exhibiting a substantially same characteristic as the crystal plane or crystal orientation. Generally, a crystal plane or crystal orientation inclined from a specific crystal plane or a crystal orientation toward a certain direction by an angle of 10 degrees or less exhibits substantially the same characteristic as the original crystal plane or crystal orientation, at least with regard to distortion characteristic or mobility.

### Details of Embodiments

Embodiments will be described in detail below. In the following, details of the embodiments will be explained in a manner divided into a plurality of parts. Unless stated otherwise, a “section” or an “embodiment” refers to what belongs to the same part, in principle.

The embodiments will be explained in further detail. In the drawings, identical or similar parts are indicated by identical or similar symbols or reference numerals, in which repetitive explanation is omitted in principle.

In the accompanying drawings, hatching of a cross-section may be omitted if it rather complicates the figure, or if distinction with a void is obvious. Similarly, the background profile line of a planarly closed hole may be omitted if it is obvious from the explanation. Furthermore, hatching may be provided to a position other than a cross-section in order to explicitly indicate that it is not a void.

<<Part 1: Mainly in Relation to the Gate First Process>>

0. Outline of Part 1:

There is a problem with a CMIS semiconductor integrated circuit using a High-k Gate insulation film that, in a device region having a short channel length and a narrow channel width, with an increase of the film thickness of an Interfacial Layer IL between the High-k Gate insulation film and a silicon-based substrate by activation annealing of source/drain regions, the absolute value of the threshold voltage of an N-type MISFET increases, and the absolute value of the threshold voltage of a P-type MISFET decreases, although the degree of change is not as large as that of the N-type MISFET. In addition, there is also a problem that oxygen in an oxide element isolation region or oxygen in a side wall silicon oxide film diffuses in a metal gate electrode, so that the metal gate electrode is oxidized to disturb the work function.

The following explains briefly the outline of a typical invention among the inventions disclosed in this part.

One of the inventions of this part is a manufacturing method of a semiconductor integrated circuit device having a MISFET, and the method includes the steps of covering the semiconductor substrate surface with an oxygen absorption film after forming a High-k gate stack and the peripheral structure of the MISFET, performing annealing in that state to activate impurities in the source/drain, and subsequently removing the oxygen absorption film.

The following explains briefly the effect acquired by the typical invention among the inventions disclosed in this part.

Specifically, the manufacturing method of a semiconductor integrated circuit device having a metal insulator semiconductor field effect transistor (MISFET) covers the semiconductor substrate surface with an oxygen absorption film after forming a High-k gate stack and the peripheral structure of the MISFET, performs annealing in the above state to activate impurities in the source/drain, and subsequently removes the oxygen absorption film, and then increase of the threshold voltage (the absolute value, to be accurate) of a MISFET having a short channel length and a narrow channel width due to undesired increase of an film thickness of an interfacial silicon oxide film during heat treatment can be controlled.

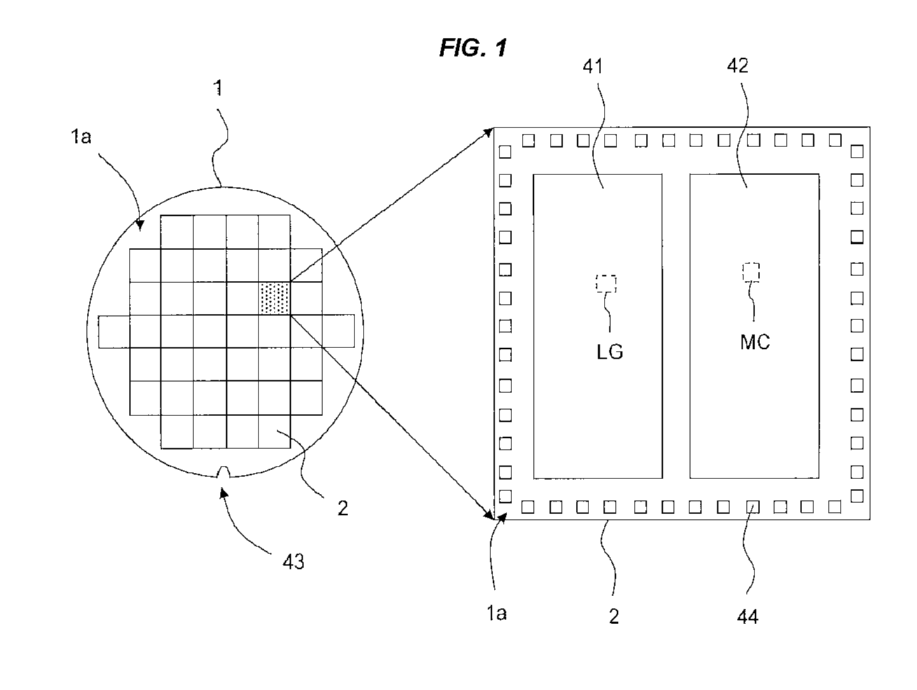

1. Explanation of a CMOS chip which is a target device in the manufacturing method of a semiconductor integrated circuit device in accordance with embodiments of the present application (mainly, FIGS. 1 to 4)

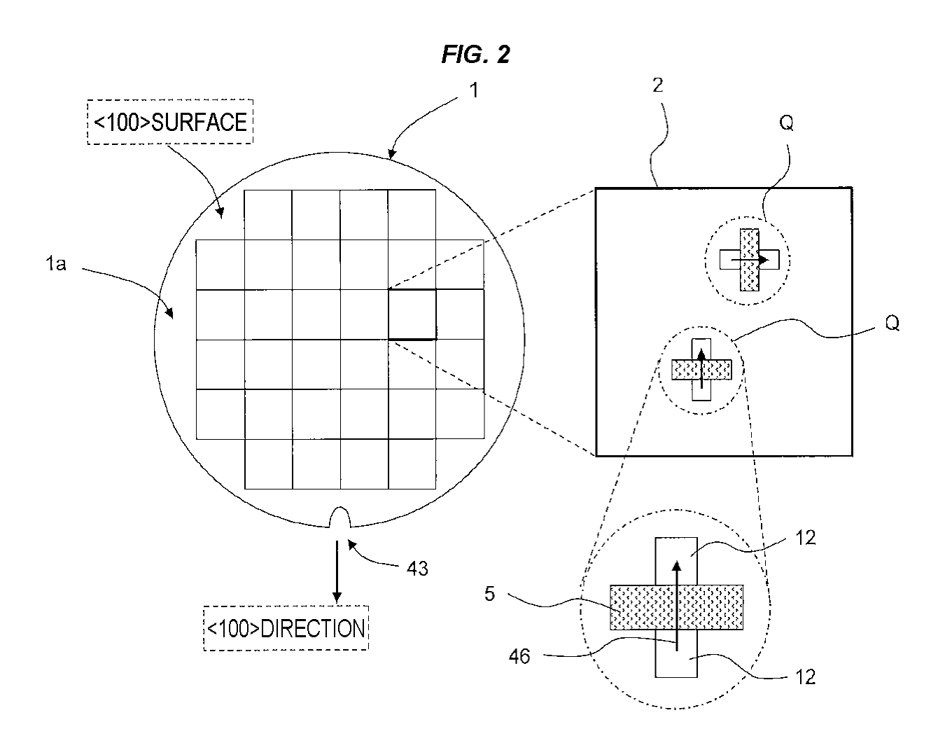

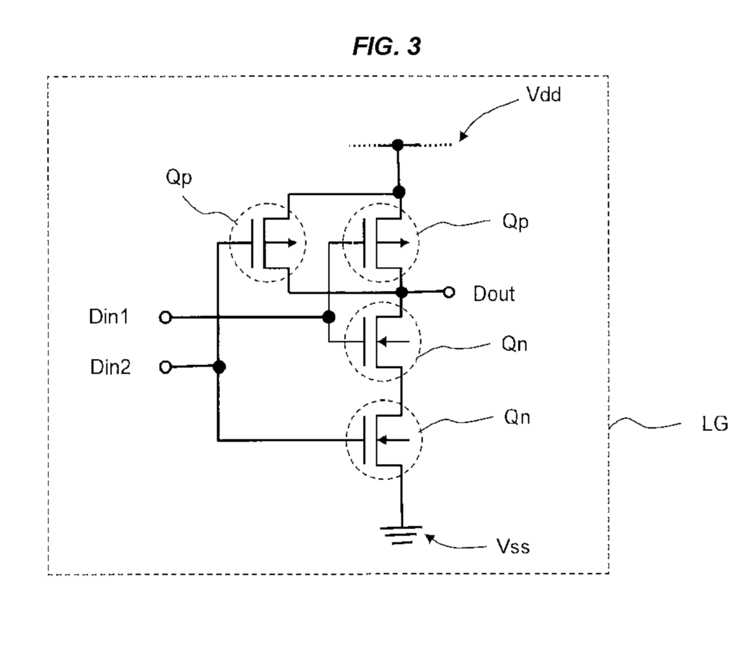

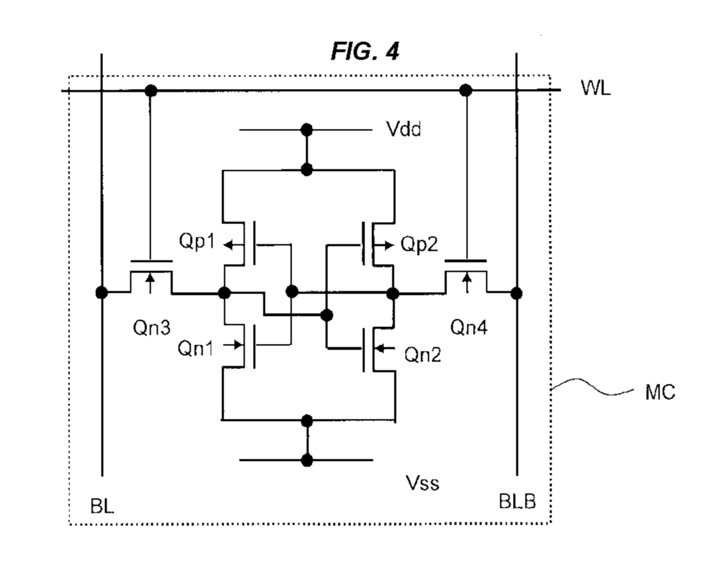

FIG. 1 is a top plan view of a wafer and a semiconductor chip showing a top surface layout of the CMOS chip which is a target device in the manufacturing method of a semiconductor integrated circuit device in accordance with each embodiment of the present application. FIG. 2 is a schematic top plan view of a wafer and a semiconductor chip showing a relation between a channel direction and a crystal plane orientation over the chip in FIG. 1. FIG. 3 is a circuit diagram showing a circuit configuration of a logic gate LG over the semiconductor chip in FIG. 1. FIG. 4 is a circuit diagram showing a circuit configuration of a memory cell MC over the semiconductor chip in FIG. 1. Based on these drawings, a CMOS chip which is a target device in the manufacturing method of a semiconductor integrated circuit device in accordance with each embodiment of the present application will be explained.

As shown in FIG. 1, a large number of chip regions 2 are formed on a device main surface 1a (first main surface) of a wafer 1 (although a 300 φ silicon single crystal wafer is exemplified, the diameter may be either 450 φ or 200 φ) in the course of the wafer processing. In addition, the wafer 1 is provided with a notch 43 to determine its alignment.

Details of the layout of each chip 2 (chip region) will be explained. A large number of bonding pads 44 are provided in the periphery of the chip region 2, and the internal region has a memory circuit region 42 and an operation and logic circuit region 41 (simply referred to as “logic circuit region”) are provided in this periphery.

Although a static random access memory (SRAM) is exemplified as the memory region 42, it is not limited to an SRAM and either a dynamic random access memory (DRAM) or a flash memory may also be used.

Next, referring to FIG. 2, relation between the plane orientation of the wafer 1, the alignment of the chip 2, and the channel direction 46 of the MISFET (Q) (referred to as “crystal orientation relation”) will be explained. The crystal orientation relation can be set relatively freely as necessary and thus it is assumed that the crystal plane of the device main surface 1a (first main surface) is the (100) plane or a plane equivalent to the (100) plane (equivalent planes are included by simply referring to the “(100) plane”), and the direction the notch 43 is the <100> direction (including equivalent directions and the same goes in the following), as shown in FIG. 2 as an example. The wafer 1 is abbreviated as a (100)/<100> wafer. A (100)/<110> wafer, a (100)/<111> wafer or the like are also preferred wafers other than that mentioned above.

In the chip 2 over the (100)/<100> wafer 1, the channel direction 46 of the MISFET (Q) (the direction connecting source/drain regions 12 that face each other with a gate electrode 5 sandwiched) usually aligns with the direction along the X- or Y-axis of the chip 2. A different alignment is allowed for a specific purpose.

Next, referring to FIGS. 3 and 4, a specific example of circuits of the logic circuit region 41 and the memory circuit region 42 in FIG. 1 will be briefly explained. A large number of various logic gates LG (CMOS-NAND gates) are provided in the logic circuit region 41. As shown in FIG. 3, a logic gate LG includes a power source terminal Vdd (power line), a ground terminal Vss (ground line), one or more input terminals Din1 and Din2, an output terminal Dout, an N-type MISFET (Qn) and a P-type MISFET (Qp) which form the gate.

Furthermore, as shown in FIG. 4, the memory circuit region 42 (SRAM) includes an extremely large number of memory cells MC arranged in a matrix. Each memory cell MC includes the power source terminal Vdd (power line), the ground terminal Vss (ground line), a word line WL, a pair of bit lines BL and BLB, a pair of N-type read transistors Qn3 and Qn4, a pair of N-type memory transistors Qn1 and Qn2, and a pair of P-type memory transistors Qp1 and Qp2.

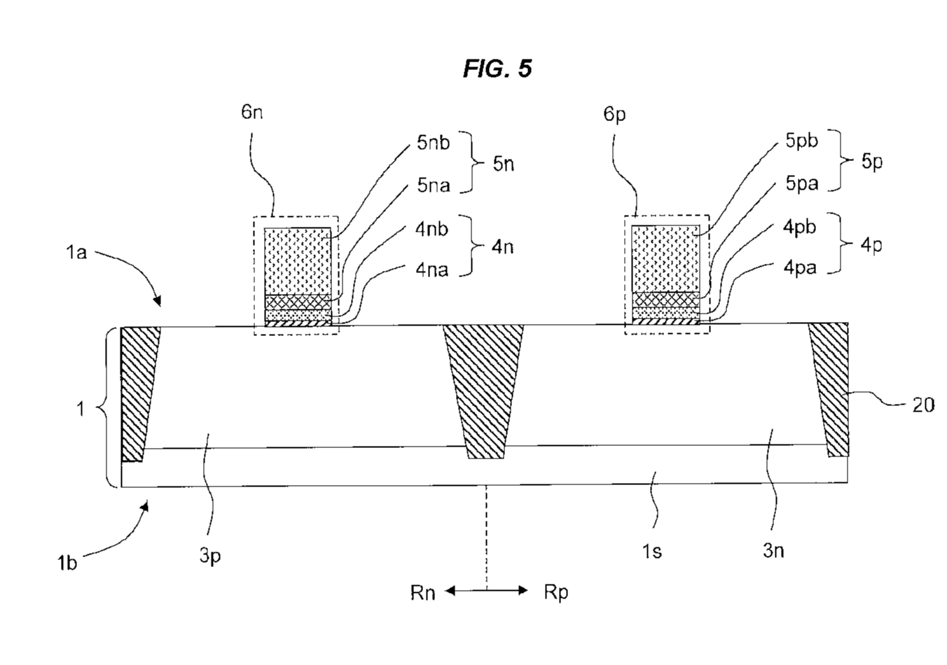

2. Explanation of a process flow in the manufacturing method of a semiconductor integrated circuit device in accordance with an embodiment of the present application (see mainly FIGS. 5 to 22, and FIGS. 29 and 30)

Although specific description is provided below with a 28 nm technology node device is exemplified, the process flow can be applied to any other technology node devices.

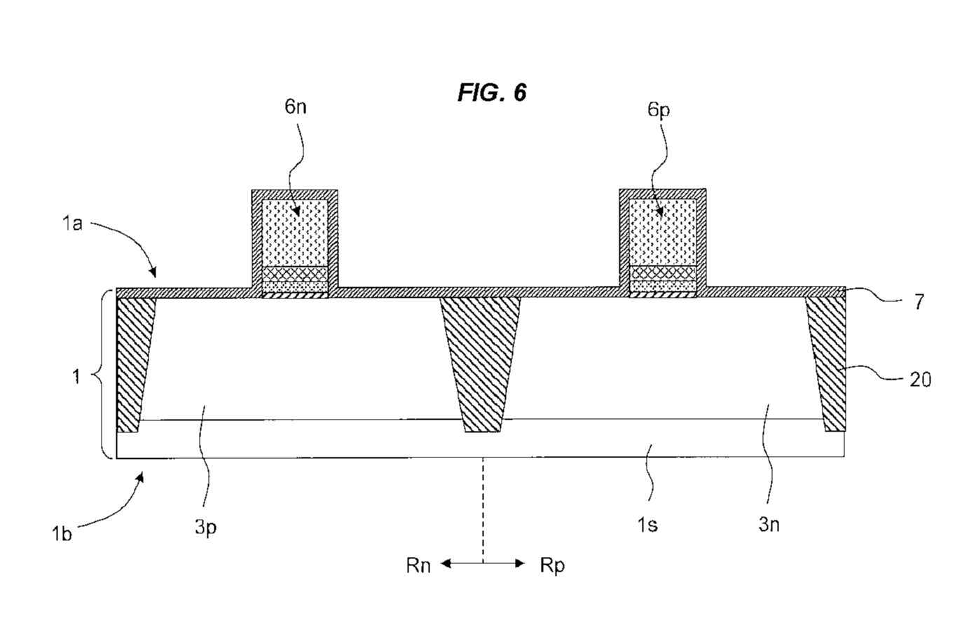

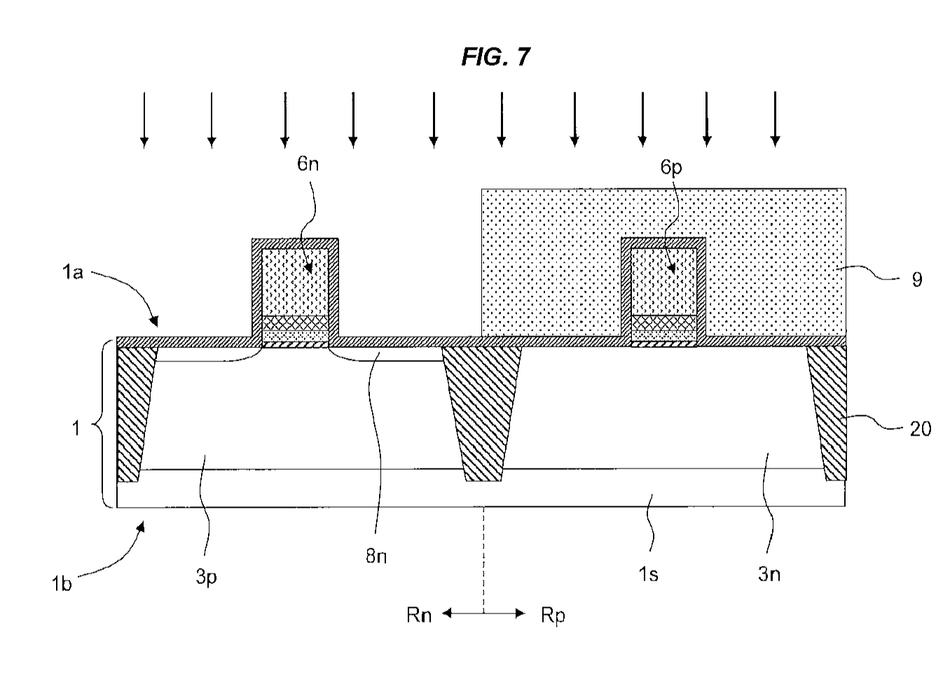

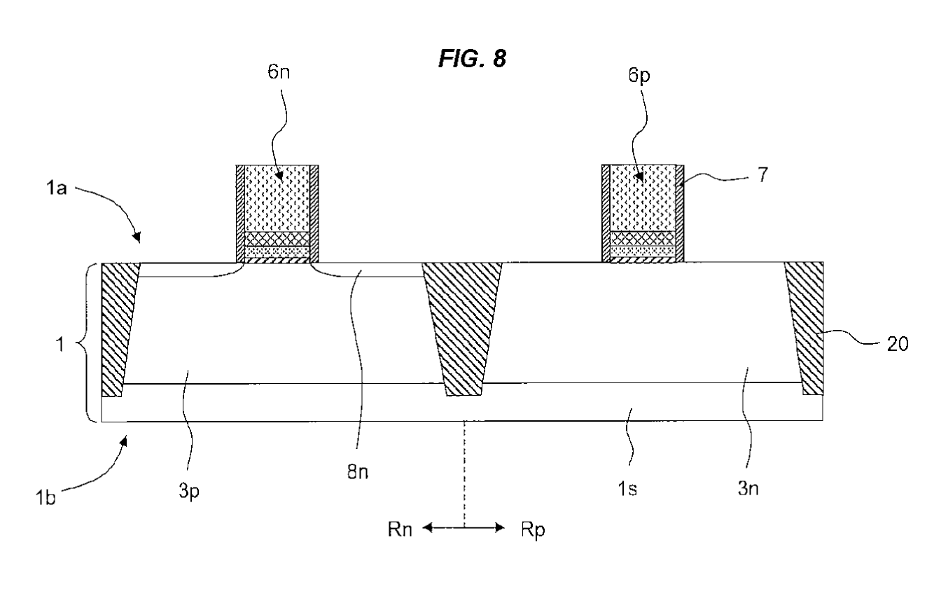

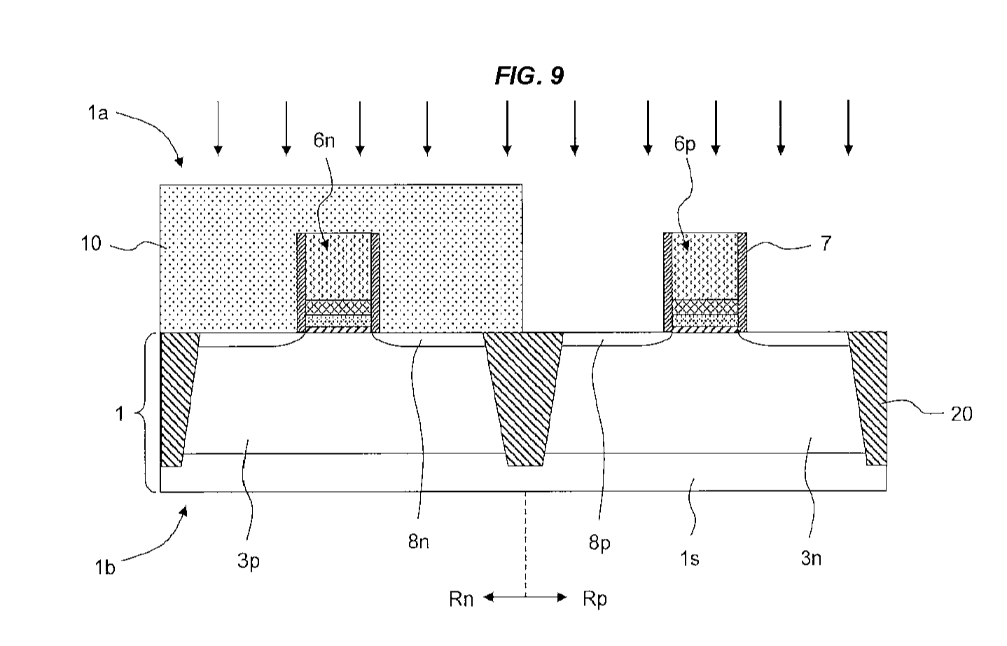

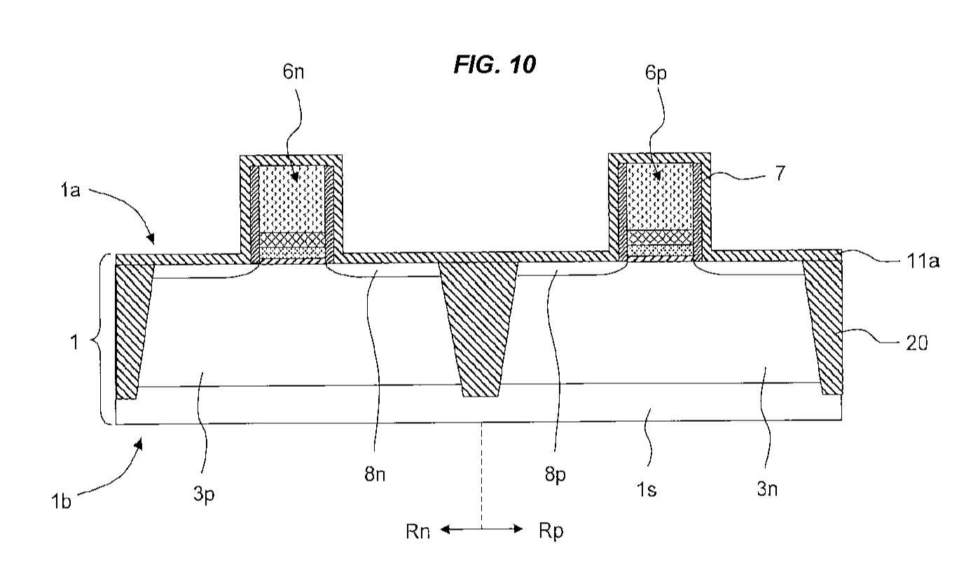

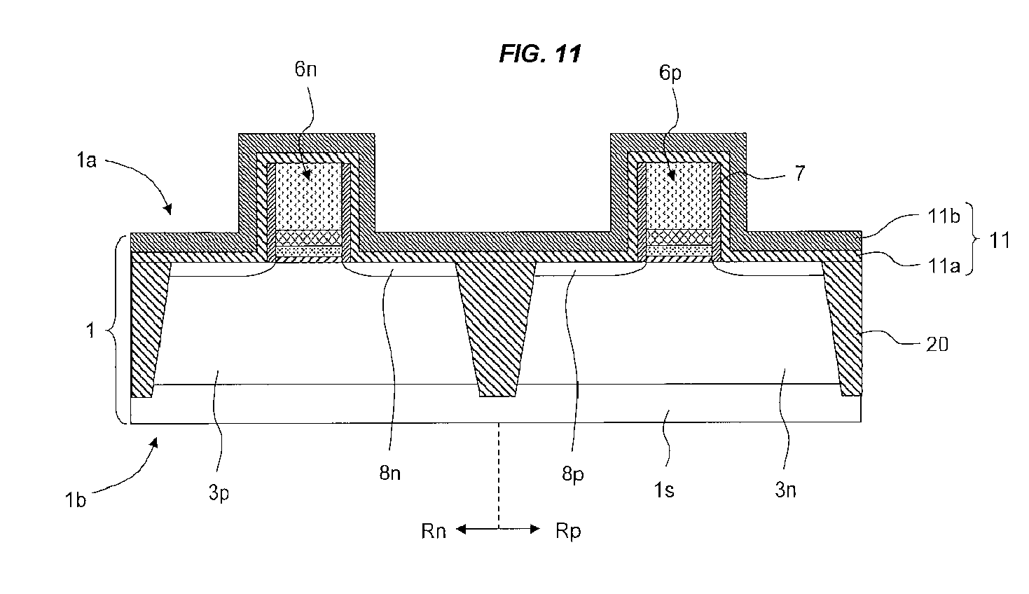

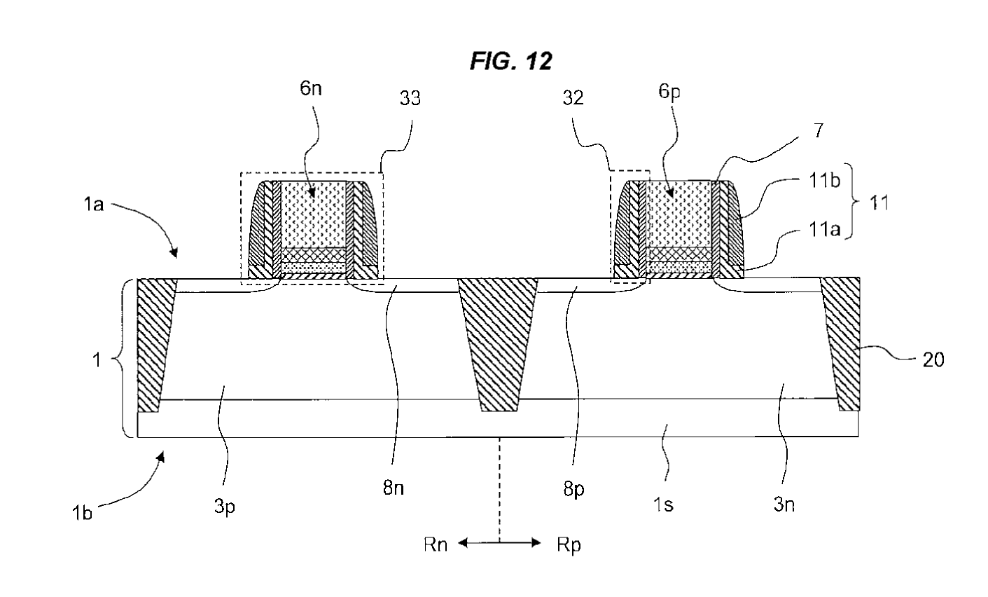

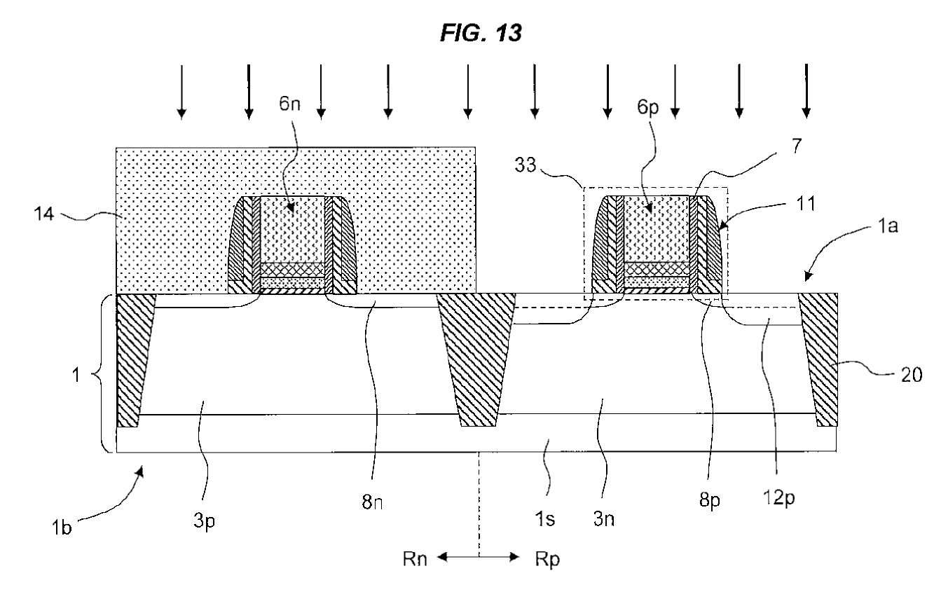

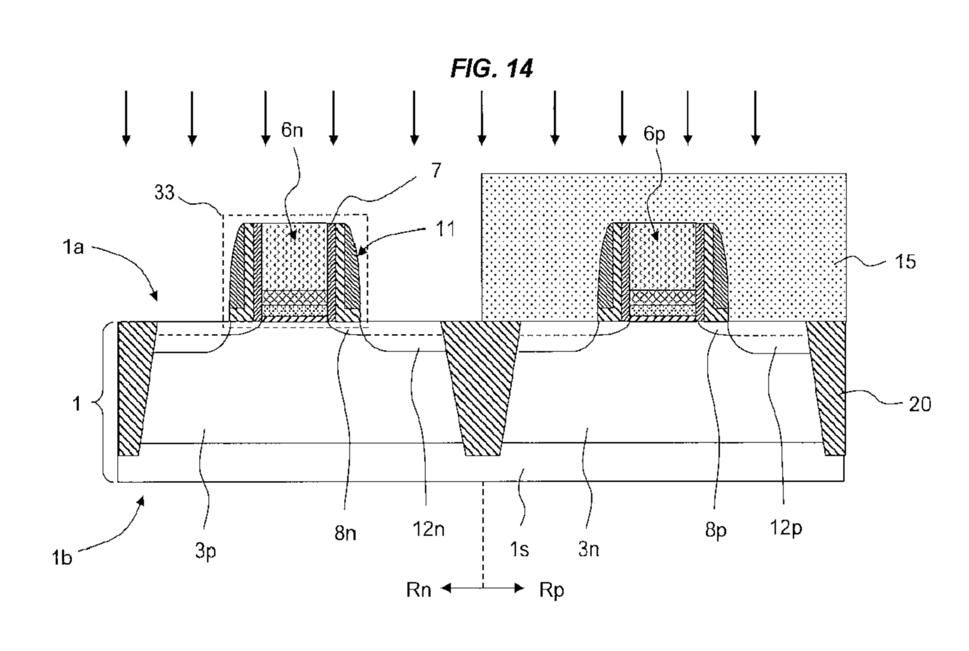

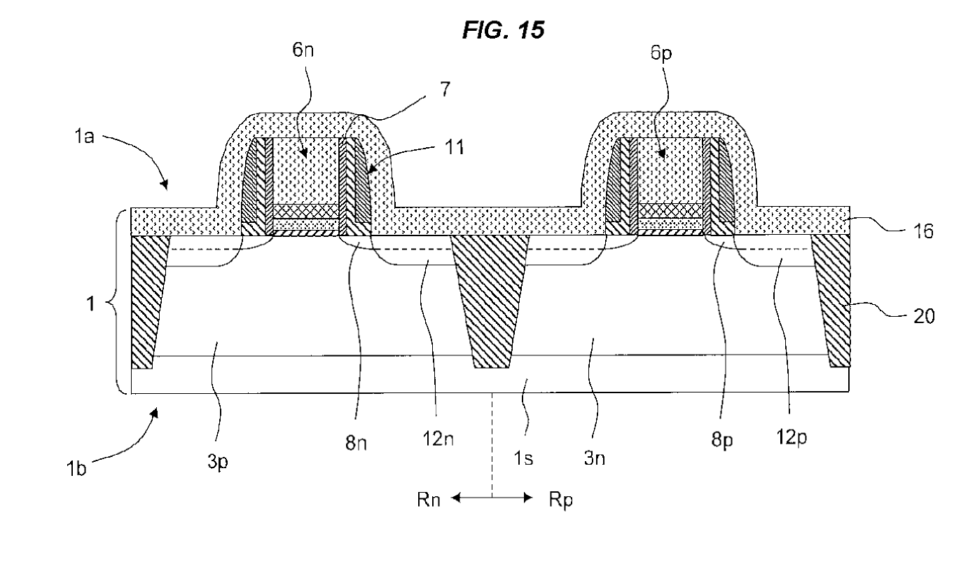

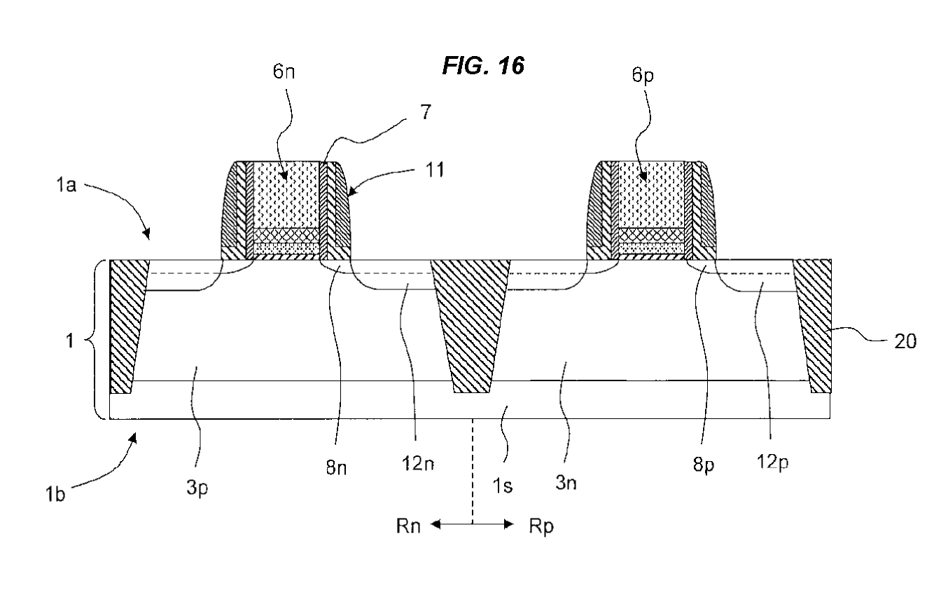

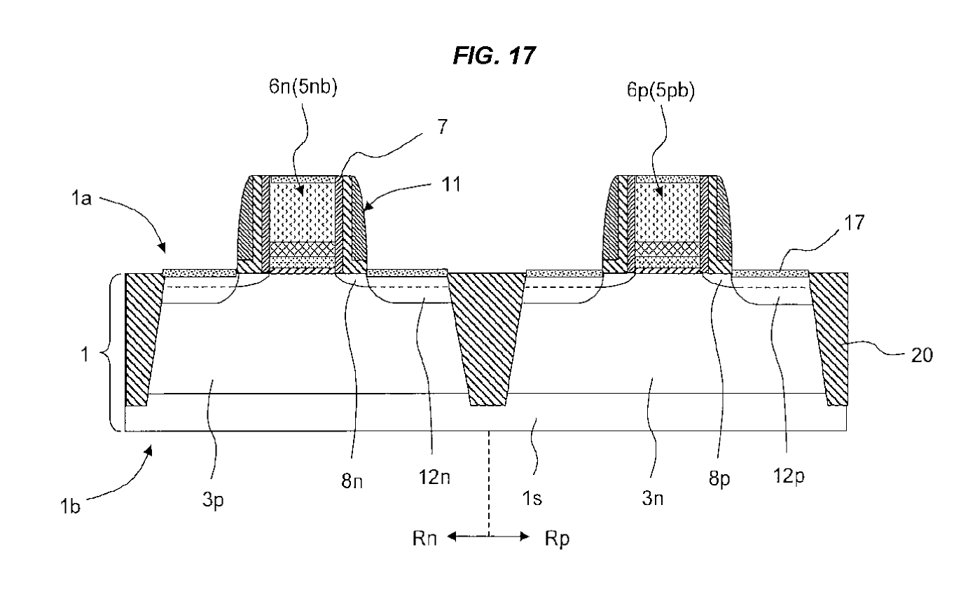

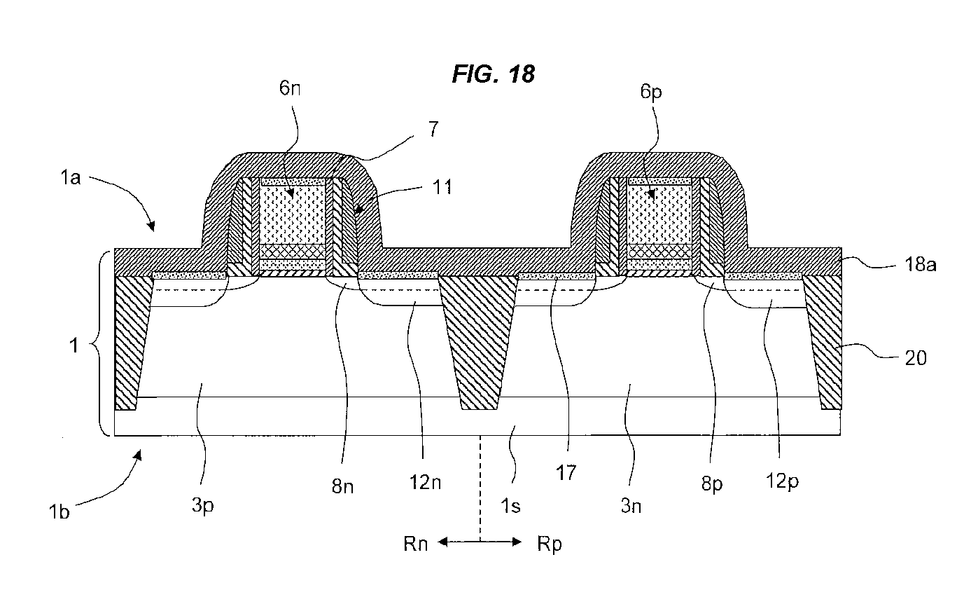

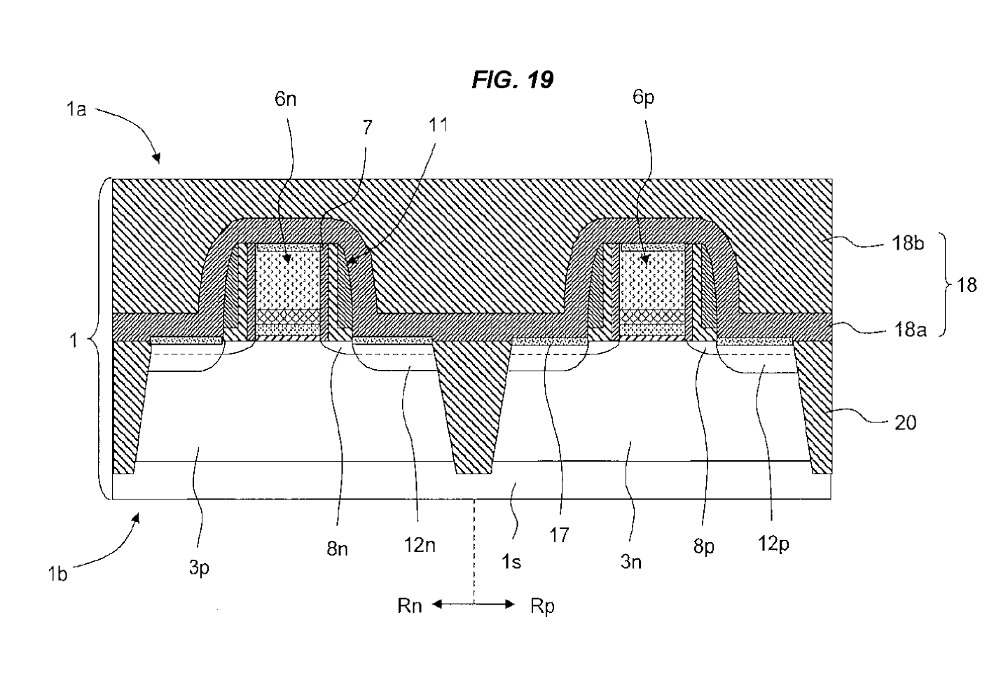

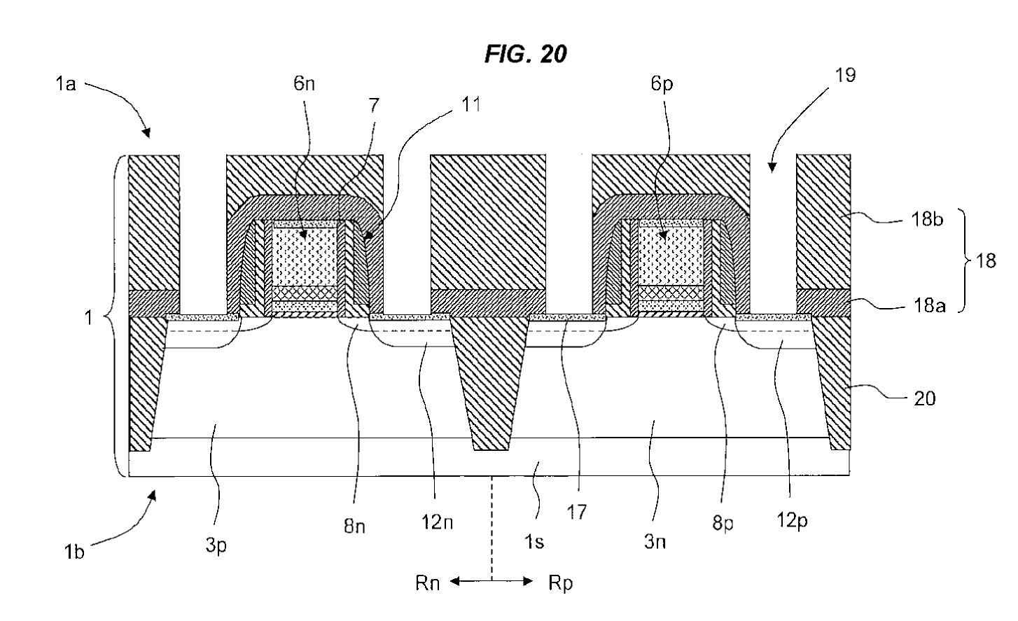

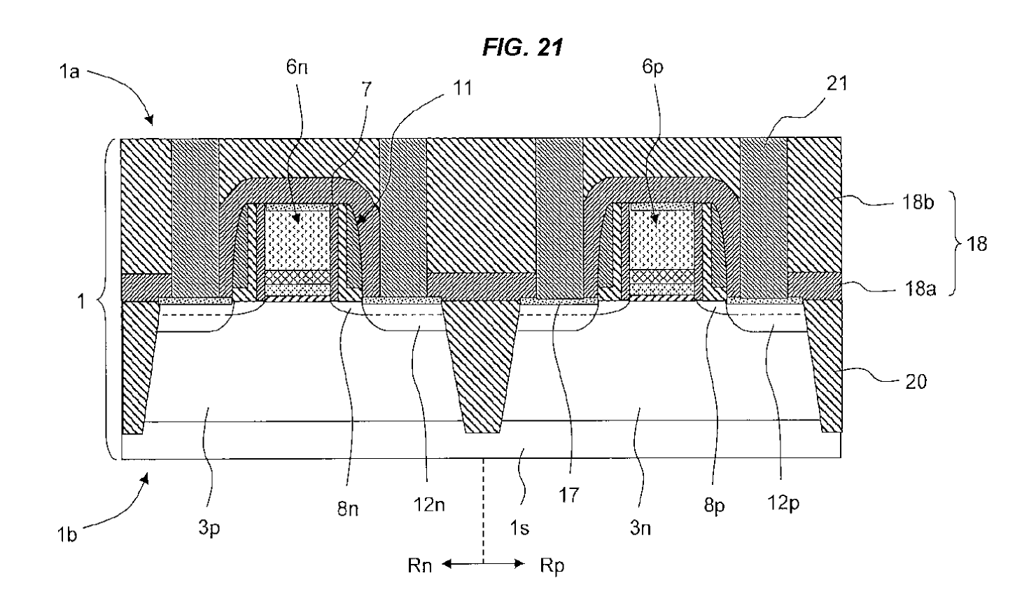

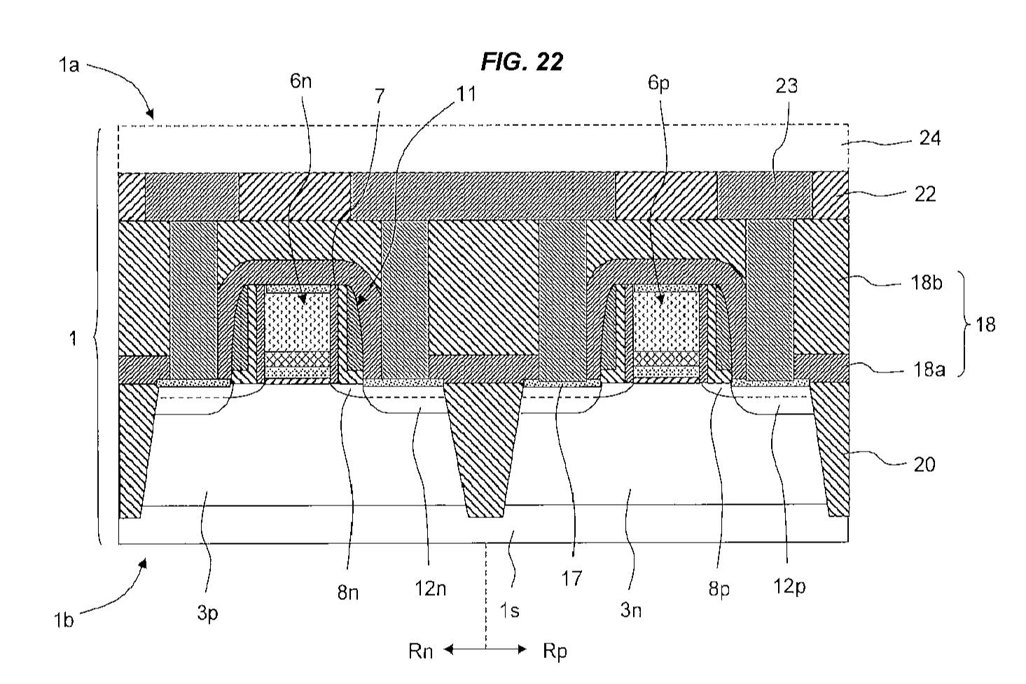

FIG. 5 is a partial cross sectional view of a wafer (at the time of completing fabrication of the gate stack) for explaining a CMIS process flow in the manufacturing method of a semiconductor integrated circuit device in accordance with an embodiment of the present application. FIG. 6 is a partial cross-sectional view of a wafer (at the time of forming an offset spacer silicon nitride film) for explaining the CMIS process flow in the manufacturing method of a semiconductor integrated circuit device in accordance with an embodiment of the present application. FIG. 7 is a partial cross-sectional view of a wafer (at the time of introducing an N-type source/drain extension region) for explaining the CMIS process flow in the manufacturing method of a semiconductor integrated circuit device in accordance with an embodiment of the present application. FIG. 8 is a partial cross-sectional view of a wafer (at the time of etching back the offset spacer silicon nitride film) for explaining the CMIS process flow in the manufacturing method of a semiconductor integrated circuit device in accordance with an embodiment of the present application. FIG. 9 is a partial cross-sectional view of a wafer (at the time of introducing a P-type source/drain extension region) for explaining the CMIS process flow in the manufacturing method of a semiconductor integrated circuit device in accordance with an embodiment of the present application. FIG. 10 is a partial cross-sectional view of a wafer (at the time of forming a side wall silicon oxide film) for explaining the CMIS process flow in the manufacturing method of a semiconductor integrated circuit device in accordance with an embodiment of the present application. FIG. 11 is a partial cross-sectional view of a wafer (at the time of forming a side wall silicon nitride film) for explaining the CMIS process flow in the manufacturing method of a semiconductor integrated circuit device in accordance with an embodiment of the present application. FIG. 12 is a partial cross-sectional view of a wafer (at the time of etching back the side wall insulation film) for explaining the CMIS process flow in the manufacturing method of a semiconductor integrated circuit device in accordance with an embodiment of the present application. FIG. 13 is a partial cross-sectional view of a wafer (at the time of introducing a P-type high density source/drain region) for explaining the CMIS process flow in the manufacturing method of a semiconductor integrated circuit device in accordance with an embodiment of the present application. FIG. 14 is a partial cross-sectional view of a wafer (at the time of introducing an N-type high density source/drain region) for explaining the CMIS process flow in the manufacturing method of a semiconductor integrated circuit device in accordance with an embodiment of the present application. FIG. 15 is a partial cross-sectional view of a wafer (at the time of forming an oxygen absorption film and activation annealing) for explaining the CMIS process flow in the manufacturing method of a semiconductor integrated circuit device in accordance with an embodiment of the present application. FIG. 16 is a partial cross-sectional view of a wafer (at the time of removing the oxygen absorption film) for explaining the CMIS process flow in the manufacturing method of a semiconductor integrated circuit device in accordance with an embodiment of the present application. FIG. 17 is a partial cross-sectional view of a wafer (at the time of completing the silicidation) for explaining the CMIS process flow in the manufacturing method of a semiconductor integrated circuit device in accordance with an embodiment of the present application. FIG. 18 is a partial cross-sectional view of a wafer (at the time of forming a CESL) for explaining the CMIS process flow in the manufacturing method of a semiconductor integrated circuit device in accordance with an embodiment of the present application. FIG. 19 is a partial cross-sectional view of a wafer (at the time of forming a silicon oxide-based premetal insulation film) for explaining the CMIS process flow in the manufacturing method of a semiconductor integrated circuit device in accordance with an embodiment of the present application. FIG. 20 is a partial cross-sectional view of a wafer (at the time of opening a contact hole) for explaining the CMIS process flow in the manufacturing method of a semiconductor integrated circuit device in accordance with an embodiment of the present application. FIG. 21 is a partial cross-sectional view of a wafer (at the time of completing the tungsten plug embedding) for explaining the CMIS process flow in the manufacturing method of a semiconductor integrated circuit device in accordance with an embodiment of the present application. FIG. 22 is a partial cross-sectional view of a wafer (at the time of completing the multilayer wiring) for explaining the CMIS process flow in the manufacturing method of a semiconductor integrated circuit device in accordance with an embodiment of the present application. Based on these drawings, a process flow in the manufacturing method of a semiconductor integrated circuit device in accordance with an embodiment of the present application will be explained.

As shown in FIG. 5, a P-well region 3p and an N-well region 3n separated by a shallow trench isolation (STI) region (oxide element isolation region) 20 are provided on the device surface (first main surface) 1a side (the other side of the back surface 1b) of a substrate is (with a specific resistance of about 1 to 10 Ωcm) of the P-type single crystal silicon wafer 1. The part provided with the P-well region 3p corresponds to an N-type MISFET region Rn, and the part provided with the N-well region 3n corresponds to a P-type MISFET region Rp. A gate stack 6n of the N-type MISFET is provided over the device surface 1a of the N-type MISFET region Rn, and a gate stack 6p of the P-type MISFET is provided over the device surface 1a of the P-type MISFET region Rp. Formation of the STI region (oxide element isolation region) 20 is performed by normal dry etching, embedding of a silicon oxide-based insulation film by chemical vapor deposition (CVD), a planarizing process by chemical mechanical deposition (CMP), or the like.

The gate stack 6n includes, in the order from the bottom, a gate insulation film 4n and a gate electrode 5n. The gate insulation film 4n includes, in the order from the bottom, an interfacial layer gate insulation film 4na (about 1 nm thick) such as a silicon oxide-based film (including a silicon oxynitride film), and a High-k Gate insulation film 4nb (about 1.5 nm thick) such as a hafnium oxide-based insulation film added with lanthanum. The gate electrode 5n includes, in the order from the bottom, a metal gate electrode 5na including titanium nitride (about 10 nm thick), and a poly-Si gate electrode 5nb (about 50 nm thick). The gate stack 6p includes, in the order from the bottom, a gate insulation film 4p and a gate electrode 5p. The gate insulation film 4p includes, in the order from the bottom, an interfacial gate insulation film 4pa (about 1 nm thick, for example) such as a silicon oxide-based film (including a silicon oxynitride film), and a High-k Gate insulation film 4pb (about 1.5 nm thick) such as a hafnium oxide-based insulation film added with aluminum. The gate electrode 5p includes, in the order from the bottom, a metal gate electrode 5pa including titanium nitride (about 10 nm thick), and a poly-Si gate electrode 5pb (about 50 nm thick). Formation of the gate stacks 6n and 6p is performed by thermal oxidation, atomic layer deposition (AVD), sputtering film formation, CVD, anisotropic dry etching, or the like.

Next, as shown in FIG. 6, an offset spacer silicon nitride film 7 (about 10 nm thick) is formed by CVD on almost entire surface of the device surface 1a of the wafer 1.

Next, as shown in FIG. 7, an N-type source/drain extension region 8n is introduced on the semiconductor substrate surface at both sides of the gate stack 6n by ion implantation in a state of covering the P-type MISFET region Rp with an N-type source/drain extension region introduction resist film 9 by normal lithography. Preferred ion implantation conditions can be exemplified as follows: Ion type: As, implanting energy: 1 KeV to 10 KeV, dose amount: 1×10¹⁵/cm² to 9×10¹⁵/cm²; and ion type: C, implanting energy: 1 KeV to 5 KeV, dose amount: 4×10¹⁴/cm² to 9×10¹⁴/cm².

Subsequently, the resist film 9 which has become unnecessary is removed by asking or the like.

Next, as shown in FIG. 8, a silicon nitride-based offset spacer 7 is formed by anisotropic dry etching.

Next, as shown in FIG. 9, a P-type source/drain extension region is introduced on the semiconductor substrate surface at both sides of the gate stack 6p by ion implantation in a state of covering the N-type MISFET region Rn with a P-type source/drain extension region introduction resist film 10 by normal lithography. Ion implantation conditions can be

exemplified as follows: Ion type: BF2, implanting energy: 1 KeV to 5 KeV, dose amount: 1×10¹⁵/cm² to 8×10¹⁵/cm²; and ion type: C, implanting energy: 1 KeV to 5 KeV, dose amount: 4×10¹⁴/cm² to 9×10¹⁴/cm².

Subsequently, the resist film 10 which has become unnecessary is removed by asking or the like.

Next, as shown in FIG. 10, a side wall silicon oxide-based film 11a (about 10 nm thick) is formed by CVD on almost entire surface of the device surface 1a of the wafer 1.

Next, as shown in FIG. 11, a side wall silicon nitride film 11b (about 20 nm thick) is formed by CVD on almost entire surface of the device surface 1a of the wafer 1. The side wall insulation film 11 includes the side wall silicon oxide film 11a and the side wall silicon nitride film 11b.

Next, as shown in FIG. 12, a side wall 11 including the silicon oxide-based side wall 11a and the silicon nitride-based side wall 11b is formed by anisotropic dry etching. The structure including the silicon nitride-based offset spacer 7 and the side wall insulation film 11 is referred to as a gate side surface structure 32. In addition, the structure including the gate stacks (6n and 6p) and the gate side surface structure 32 is referred to as a gate structure 33.

Next, as shown in FIG. 13, a P-type high density source/drain region 12p is introduced on the semiconductor substrate surface at both sides of the gate structure 33 of the P-type MISFET by ion implantation in a state of covering the N-type MISFET region Rn with a P-type high density source/drain region introduction resist film 14 by normal lithography. Ion implantation conditions can be exemplified as follows: Ion type: B, implanting energy: 0.5 KeV to 20 KeV, dose amount: 1×10¹⁵/cm² to 8×10¹⁵/cm².

Subsequently, the resist film 14 which has become unnecessary is removed by ashing or the like.

Next, as shown in FIG. 14, an N-type high density source/drain region 12n is introduced on the semiconductor substrate surface at both sides of the gate structure 33 of N-type MISFET by ion implantation in a state of covering the P-type MISFET region Rp with an N-type high density source/drain region introduction resist film 15 by normal lithography. Ion implantation conditions can be exemplified as follows: Ion type: As, implanting energy: 2 KeV to 40 KeV, dose amount: 8×10¹⁴/cm² to 4×10¹⁵/cm²; and ion type: P, implanting energy: 10 KeV to 80 KeV, dose amount: 1×10¹³/cm² to 8×10¹³/cm².

Subsequently, the resist film 15 which has become unnecessary is removed by ashing or the like.

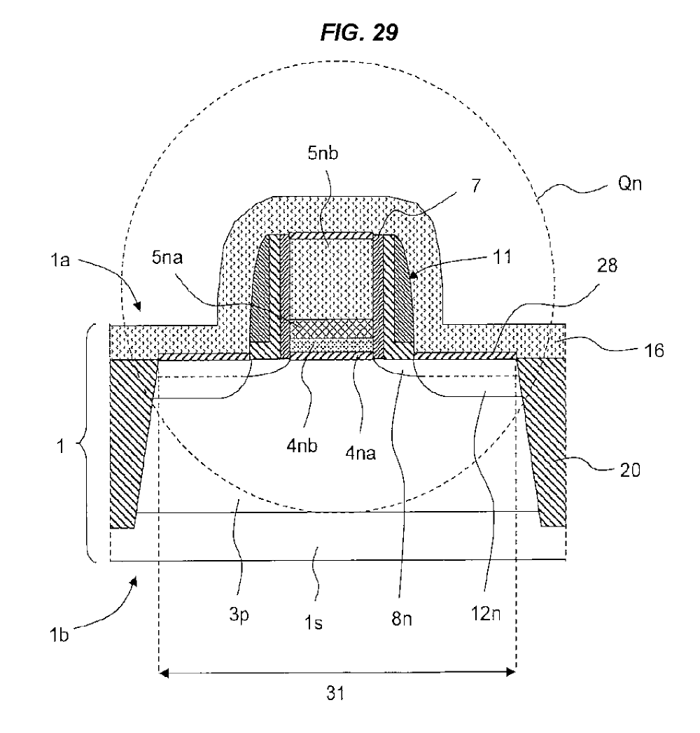

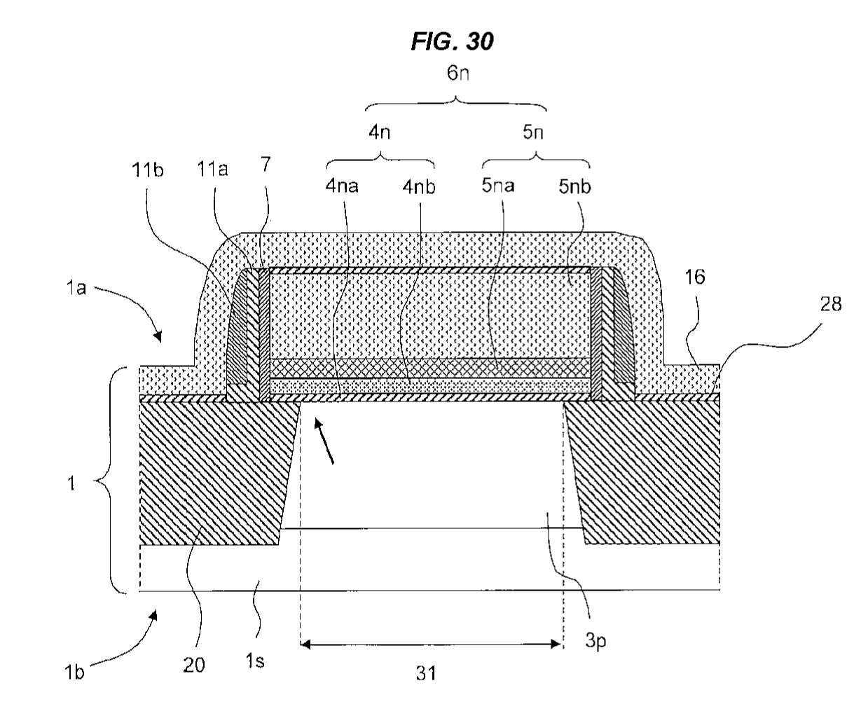

Next, as shown in FIG. 15, an oxygen absorption film 16 such as an amorphous Si film (about 30 nm thick) is formed by CVD on almost entire surface of the device surface 1a of the wafer 1. Preferred temperatures for forming the oxygen absorption film 16 can be exemplified such as 400 to 500 degrees Celsius (preferred film-forming temperatures can be exemplified such as 450 to 650 degrees Celsius if the oxygen absorption film 16 is a polysilicon film). It is preferred to form a second silicon oxide-based insulation film (a thin-film silicon oxide-based film 28 with a thickness of about 1 nm (referred to as an “ashing silicon oxide film”)) on the silicon surface of the device surface 1a of the wafer 1 by a plasma oxidation process in the oxygen atmosphere (asking oxidation process), before forming the oxygen absorption film 16 (see FIGS. 29 and 30). This is performed for preventing damage to the silicon surface of the device surface 1a of the underlying wafer 1 when the oxygen absorption film 16 is removed.

Subsequently, high temperature anneal is performed to activate the injected impurities with the oxygen absorption film 16 having been formed. Preferred high temperature anneal can be exemplified such as a combination of spike RTA (about 1 second at about 1000 degrees Celsius) and laser spike anneal (LSA). The preferred condition of LSA can be exemplified such as a unit spike at about 1200 degrees Celsius.

The oxygen absorption film 16 may be a poly-Si film (about 30 nm thick). However, because the oxygen absorption film 16 also acts as a stress applying film, an amorphous Si film is more advantageous to the stress applying operation.

Next, as shown in FIG. 16, the whole oxygen absorption film 16 is removed. The oxygen absorption process is completed by this. Removal of the oxygen absorption film is performed using an alkali-based etchant such as ammonia/hydrogen peroxide solution, using an ashing silicon oxide film as an etch-stop film. The ashing silicon oxide film is removed by subsequent cleaning using hydrofluoric acid-based cleaning liquid.

Next, as shown in FIG. 17, a nickel silicide-based silicide film 17 (Ni Pt silicide) is formed over the N-type high density source/drain region 12n, the P-type high density source/drain region 12p, and the gate stacks 6n and 6p (poly-Si gate electrodes 5nb and 5pb) as necessary by a normal salicide process.

Next, as shown in FIG. 18, a contact etch-stop silicon nitride film 18a (about 25 nm thick) is formed on almost entire surface of the device surface 1a of the wafer 1 by CVD.

Next, as shown in FIG. 19, the contact etch-stop silicon nitride film 18a, together with a silicon oxide-based premetal insulation film 18b (usually this film is thicker than the contact etch-stop silicon nitride film 18a, being about 200 nm thick) constituting a premetal insulation film 18, is formed on almost entire surface of the device surface 1a of the wafer 1 by CVD. Subsequently the surface is planarized as necessary by CMP or the like.

Next, as shown in FIG. 20, a contact hole 19 is opened by normal lithography.

Next, as shown in FIG. 21, a tungsten plug 21 or the like is embedded in the contact hole 19.

Next, as shown in FIG. 22, a silicon oxide film-based first layer wiring insulation film 22 is formed over the premetal insulation film 18 to form a first layer embedded wiring 23 such as a copper-based embedded wiring (single damascene wiring) (an aluminum-based unembedded wiring or a mixed wiring in which embedded wiring and an unembedded wiring are applied to separate layers may be applied). After that, a similar process is repeated to form an upper multilayer wiring layer 24 (a dual damascene wiring), a final passivation film, a bonding pad and the like. Subsequently, individual chips 2 are formed via a wafer test process, a back grinding process, a dicing process and the like, and packaged as necessary into the final device.

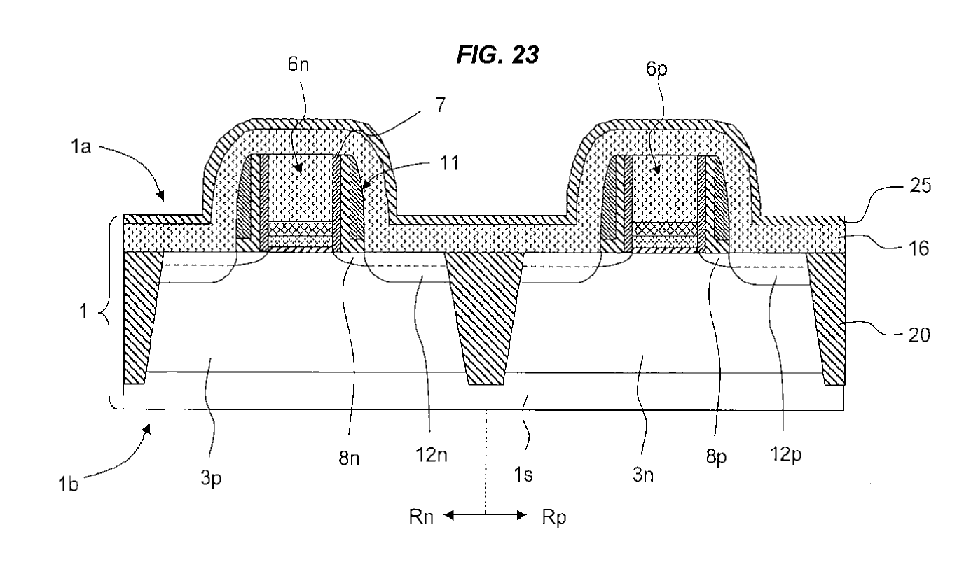

3. Explanation of a process flow in an exemplary variation of the manufacturing method of a semiconductor integrated circuit device in accordance with the embodiment of the present application (mainly, FIGS. 23 to 26)

The example of this section is an exemplary variation 1 of the oxygen absorption process of FIGS. 15 to 16 (referred to as “additional stressor overcoat approach”) of Section 2, above which a silicon nitride-based stress applying film such as a silicon nitride film is added as an additional stress applying film in order to increase the effect of applying stress which is a side effect of the oxygen absorption film 16. Therefore, with the explanation for FIGS. 5 to 22 being completely the same, only different parts (FIGS. 15 and 16) will be explained below.

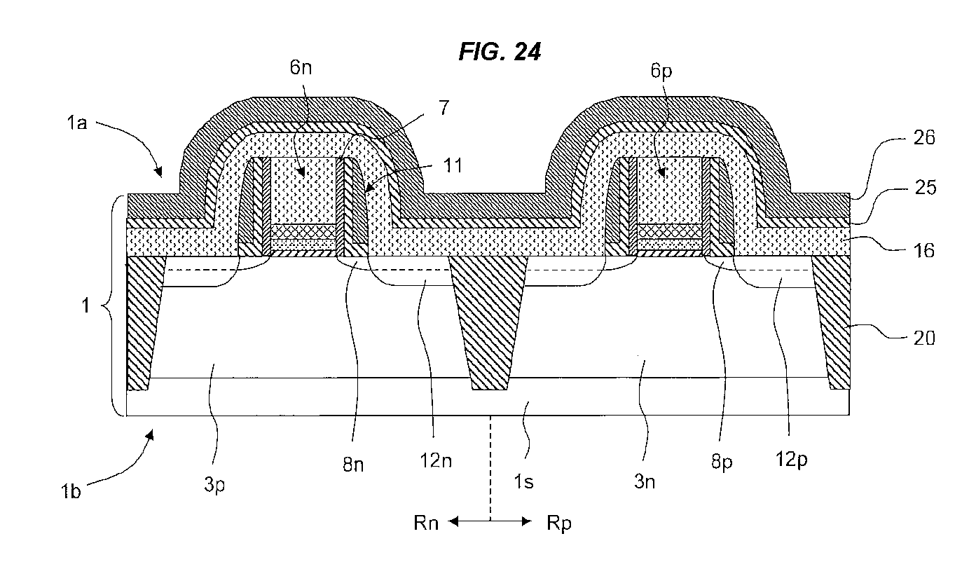

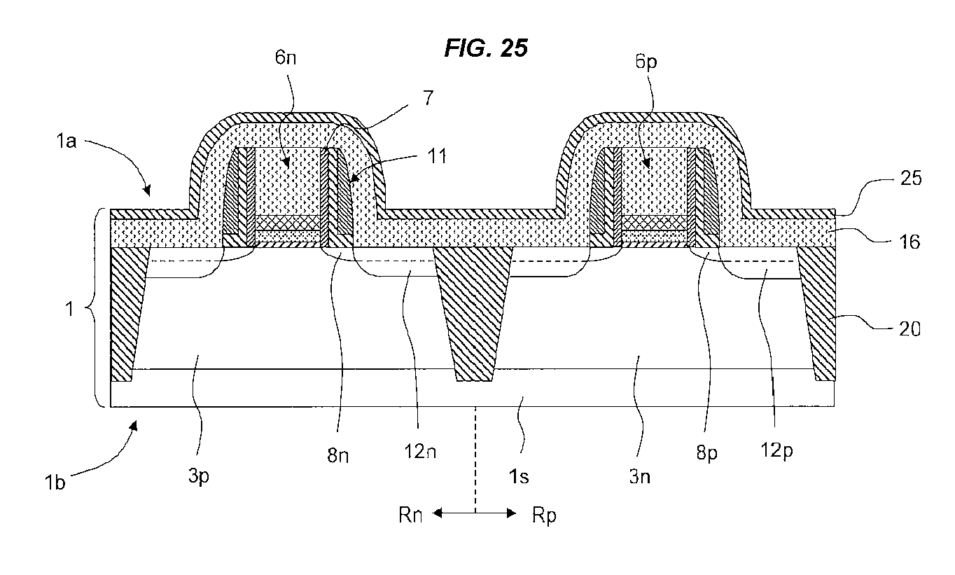

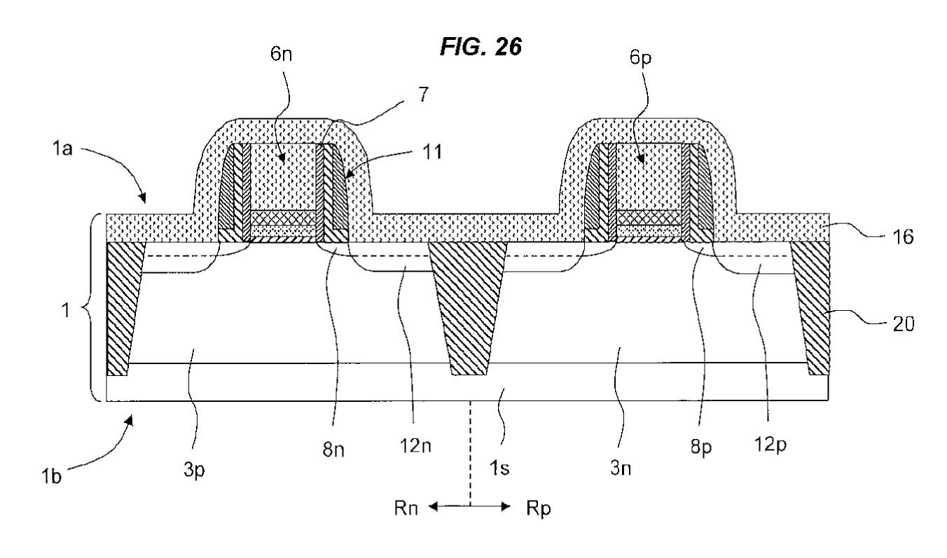

FIG. 23 is a partial cross-sectional view of a wafer (at the time of forming an intermediate silicon oxide-based thin film) for explaining a process flow in an exemplary variation of the manufacturing method of a semiconductor integrated circuit device in accordance with an embodiment of the present application. FIG. 24 is a partial cross-sectional view of a wafer (at the time of forming a silicon nitride-based stressor film and activation annealing) for explaining a process flow in an exemplary variation of the manufacturing method of a semiconductor integrated circuit device in accordance with an embodiment of the present application. FIG. 25 is a partial cross-sectional view of a wafer (at the time of removing the silicon nitride-based stressor film) for explaining a process flow in an exemplary variation of the manufacturing method of a semiconductor integrated circuit device in accordance with an embodiment of the present application. FIG. 26 is a partial cross-sectional view of a wafer (at the time of removing the intermediate silicon oxide-based thin film) for explaining a process flow in an exemplary variation of the manufacturing method of a semiconductor integrated circuit device in accordance with an embodiment of the present application. Based on these drawings, a process flow in an exemplary variation of the manufacturing method of a semiconductor integrated circuit device in accordance with the embodiment of the present application will be explained.

As shown in FIG. 23, following FIG. 15, an intermediate silicon oxide-based thin film 25 (about 10 nm thick) such as a relatively thin (thinner than the oxygen absorption film 16) silicon oxide-based film (a first silicon oxide-based insulation film) is formed on almost entire surface over the oxygen absorption film 16 (oxygen absorption amorphous Si film or oxygen absorption poly Si film) by CVD.

Next, as shown in FIG. 24, a relatively thick (thicker than the oxygen absorption film 16) silicon nitride-based stressor film 26 (about 30 nm thick) such as a silicon nitride film is formed on almost entire surface over the intermediate silicon oxide-based film 25 by CVD.

Subsequently, high temperature anneal is performed to activate the injected impurities, with the oxygen absorption film 16, the intermediate silicon oxide-based thin film 25, and the silicon nitride-based stressor film 26 having been formed.

Next, as shown in FIG. 25, the silicon nitride-based stressor film 26 is entirely removed. Removal of the silicon nitride-based stressor film 26 is performed by wet treatment using heated phosphoric acid.

Next, as shown in FIG. 26, the intermediate silicon oxide-based thin film 25 is entirely removed. Removal of the intermediate silicon oxide-based thin film 25 is performed using hydrofluoric acid-based silicon oxide film etchant solution.

Subsequently, removing the whole oxygen absorption film 16 results in the state in FIG. 16. Removal of the oxygen absorption film 16 is performed using alkali etchant solution such as ammonia/hydrogen peroxide solution, using the ashing silicon oxide film as an etch-stop film. The ashing silicon oxide film is removed by subsequent cleaning using hydrofluoric acid-based cleaning liquid.

Subsequently, the previously explained processes in FIG. 16 and later are performed.

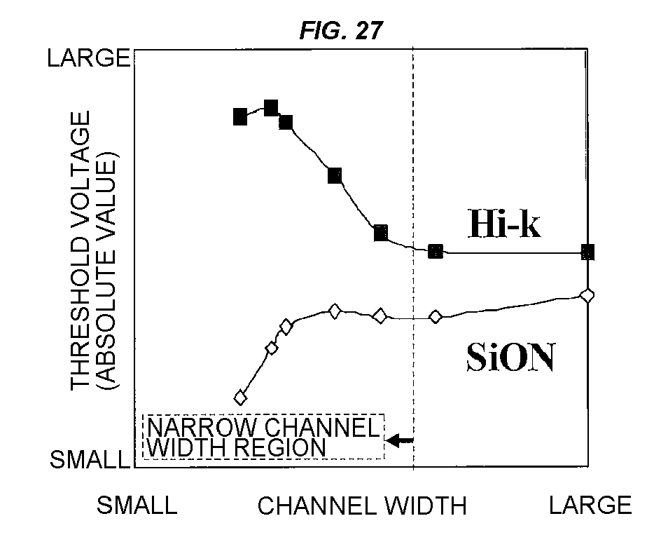

4. Consideration and supplementary explanation for the present application as a whole and the embodiments (mainly, FIGS. 27 to 30)

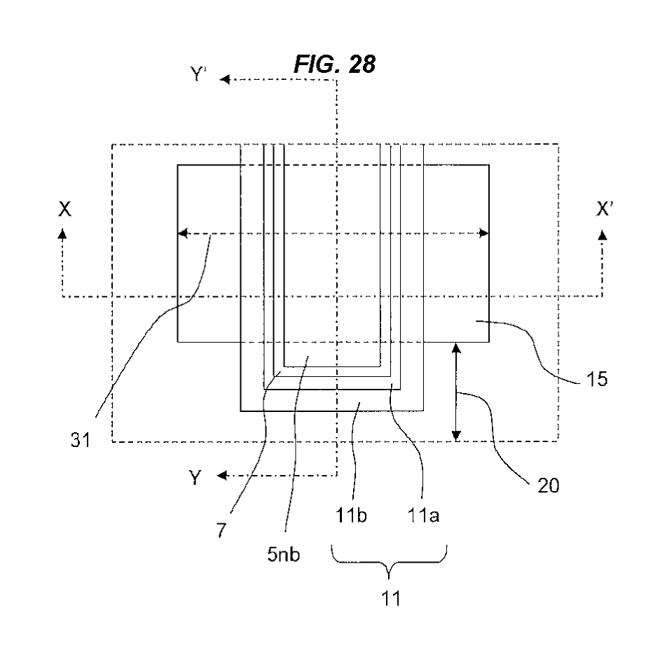

FIG. 27 is a data plot view showing dependency on channel width of a threshold voltage of a narrow channel width N-channel MISFET having a High-k Gate insulation film and a narrow channel width N-channel MISFET having an SiON gate insulation film. FIG. 28 is an enlarged top plan view of a device focusing on the N-type MISFETQn (FIG. 3) such as the logic gate LG of FIG. 1 and the periphery of the N-type MISFETQn. FIG. 29 is an enlarged cross-sectional view of a device corresponding to the section X-X′ in FIG. 28. FIG. 30 is an enlarged cross-sectional view of a device corresponding to the section Y-Y′ in FIG. 28. Based on these drawings, consideration and supplementary explanation will be provided for the overall application and embodiments.

(1) Explanation of the Mechanism Common to Embodiments:

As described above, the inventors of the present application have revealed that there is a problem with a CMIS semiconductor integrated circuit using a High-k Gate insulation film that, in a device region having a short channel length and a narrow channel width (referred to as a “narrow channel width region”), with an increase of the film thickness of an Interfacial Layer IL between the High-k Gate insulation film and a silicon-based substrate by activation annealing of source/drain regions, the absolute value of the threshold voltage increases. This situation is shown in FIG. 27. As shown in FIG. 27, although the threshold voltage tends to drop in the narrow channel width region of a short channel length MISFET having a silicon oxynitride film (SiON gate insulation film), which is a non-High-k Gate insulation film, as the gate insulation film, the threshold voltage rapidly increases in the narrow channel width region of a short channel length MISFET having an HfO-based gate insulation film which is a High-k Gate insulation film. In this case, the High-k Gate insulation film has a silicon oxide film-based underlying insulation film such as a silicon oxide film or a silicon oxynitride film as the Interfacial Layer IL underneath.

In the following, the cause and its countermeasure will be specifically explained, taking the N-type MISFET (Qn) corresponding to FIG. 15. It is considered that a high-temperature heat treatment (heat treatment with 850 degrees Celsius or higher) such as activation annealing causes oxygen in the STI region 20 (oxide element isolation region) to reach the interfacial layer gate insulation film 4na of a channel end (end of an active region 31) indicated by the arrow in FIG. 30, increasing its film thickness.

Therefore, in the embodiment described above, excessive oxygen is absorbed by providing the intervenient oxygen absorption film 16 such as an amorphous Si film nearby when performing the high-temperature heat treatment, as shown in FIGS. 28, 29, and 30.

(2) Exemplary Variation 2 (Oxygen Absorption Film Applied Only on N-Channel Side, See Mainly FIG. 15 or 24):

Although both the N-type MISFET region Rn and the P-type MISFET region Rp are covered with the oxygen absorption film 16 in the examples of sections 2 and 3, only the N-type MISFET region Rn may be covered. This is because increase of film thickness of the interfacial layer gate insulation film due to introduction of oxygen is relatively small at the P-channel side and moreover, the absolute value of the threshold voltage of the P-type MISFET decreases when oxygen is introduced in the P-type MISFET region Rp.

In this case, when applying the approach of section 3 (FIG. 24), there are an approach (first method) of applying all of the oxygen absorption film 16, the intermediate silicon oxide-based thin film 25, and the silicon nitride-based stressor film 26 to only the N-type MISFET region Rn, and an approach (second method) of applying the oxygen absorption film 16 to only the N-type MISFET region Rn and applying the intermediate silicon oxide-based thin film 25 and the silicon nitride-based stressor film 26 to all the regions. There is a merit with the first method that unnecessary oxygen is not supplied, whereas there is a merit with the second method that the effect of SMT can be obtained in both the N-type MISFET region Rn and the P-type MISFET region Rp.

(3) Selection of an Oxygen Absorption Film (See Mainly FIG. 15 or 24):

An amorphous Si film has been specifically shown in the examples of sections 2 and 3 as the material of the oxygen absorption film 16 in FIG. 15 because it is more advantageous than poly-Si film or the like in terms of thermal budget, as well as its large stress applying effect.

However, an amorphous SiGe film, a poly-SiGe film or the like can be exemplified as preferable materials other than the poly-Si film. The relation between the amorphous SiGe film and the poly-SiGe film is the same as the one between the amorphous Si film and the poly-Si film described above. In addition, thermal expansion coefficients of the SiGe film and the silicon film (amorphous Si film and poly-Si film) are different, and thus they are considered to have a large effect as a stress applying film.

5. Summary

The invention made by the inventors has been specifically described above based on embodiments, and the present invention can be modified in various ways within a range not deviating from the spirit.

Although an example using a silicon-based semiconductor film such as an amorphous Si film or a poly-Si film has been specifically described as an oxygen absorption film in the above-mentioned embodiments, the present invention is not limited to them and can be applied to an oxygen absorption film using an SiGe-based semiconductor film, a Ge-based semiconductor film, or the like.

In addition, although description in the above-mentioned embodiments has been provided, mainly taking the Gate First approach as an example, it is needless to say that the present invention is not limited thereto and can be applied to the Gate Last approach.

<<Part 2: Mainly in Relation to the Gate-Last Process>>

1. Outline of Part 2:

Although the originally considered Gate Last process remakes the entire gate stack after performing activation annealing of the source/drain regions, a High-k First/Metal gate-last approach has been put into practical use, as a gate-last approach, in terms of keeping the channel mobility and simplifying the process, in which formation of the interfacial gate insulation film (which is an interface actual gate insulation film and a dummy gate insulation film) and a High-k Gate insulation film (which is an actual gate insulation film and a dummy gate insulation film) is performed before the activation heat treatment of the source/drain, and formation of main elements of the actual gate stack on an upper layer of the High-k Gate insulation film is performed after the activation heat treatment of the source/drain. In this case, however, there is a problem, more or less, of increased film thickness of the interfacial gate insulation film (IL film) associated with the activation heat treatment, similarly to the gate-first approach described above.

The present invention is made to solve these problems. The following explains briefly the outline of a typical invention among the inventions disclosed in this part.

One of the inventions of this application part is a manufacturing method of a semiconductor integrated circuit device having a MISFET, and the method includes the steps of covering the semiconductor substrate surface with an oxygen absorption film after forming a High-k gate stack (a part of the actual gate stack or the dummy gate stack) and the peripheral structure of the MISFET, performing annealing in that state to activate impurities in the source/drain, and subsequently removing the oxygen absorption film.

The following explains briefly the effect acquired by the typical invention among the inventions disclosed in this part.

Specifically, the manufacturing method of a semiconductor integrated circuit device having a MISFET covers the semiconductor substrate surface with an oxygen absorption film after forming a High-k gate stack (a part of an intrinsic gate stack or the dummy gate stack) and the peripheral structure of the MISFET, performs annealing in the above state to activate impurities in the source/drain, and subsequently removes the oxygen absorption film, and then increase of the threshold voltage (the absolute value, to be accurate) of a MISFET having a short channel length and a narrow channel width due to undesired increase of the film thickness of an interfacial silicon oxide film during heat treatment can be controlled.

Because description of Section 1 of Part 1 is directly applicable to this part, the repetitive explanation is omitted below.

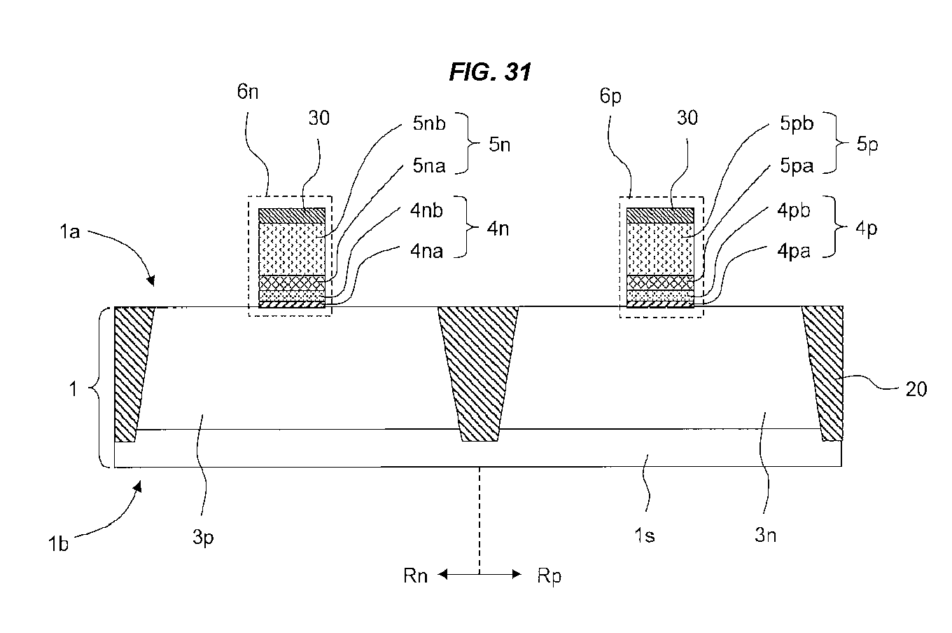

2. Explanation of a process flow (gate-last process) in the manufacturing method of a semiconductor integrated circuit device in accordance with an embodiment of Part 2 of the present application (see mainly FIGS. 31 to 55)

Although the process in the gate-last process is also basically similar to that of the gate-first process before removal of the dummy gate stack (including partial removal), a process that uses a hardmask or a cap layer (gate cap layer) can be exemplified as a preferred process due to a requirement specific to the gate-last process. The hardmask or the cap layer (gate cap layer) is not indispensable.

Although specific description is provided below with a 28-nm technology node device taken as an example, the process flow can be applied to any other technology node devices.

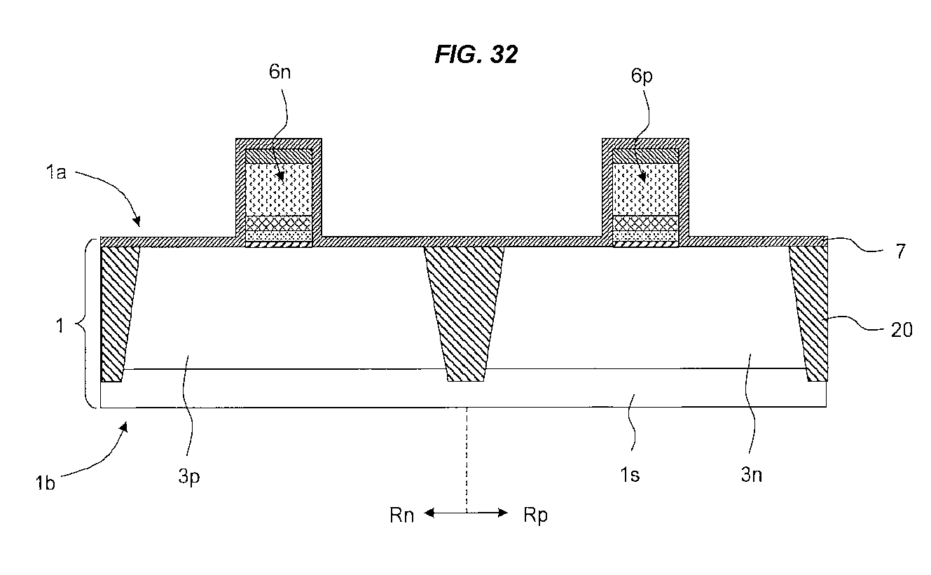

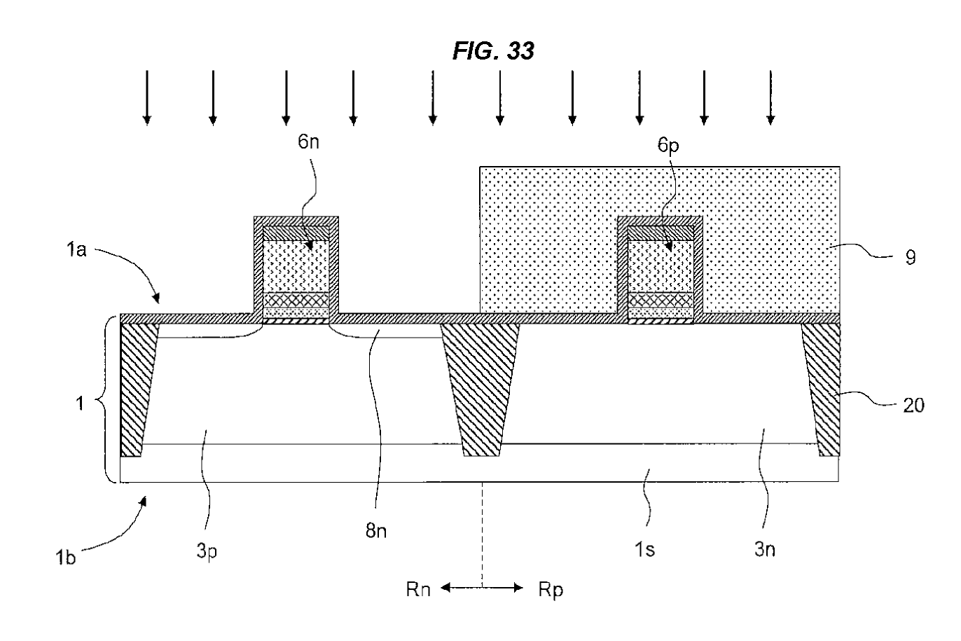

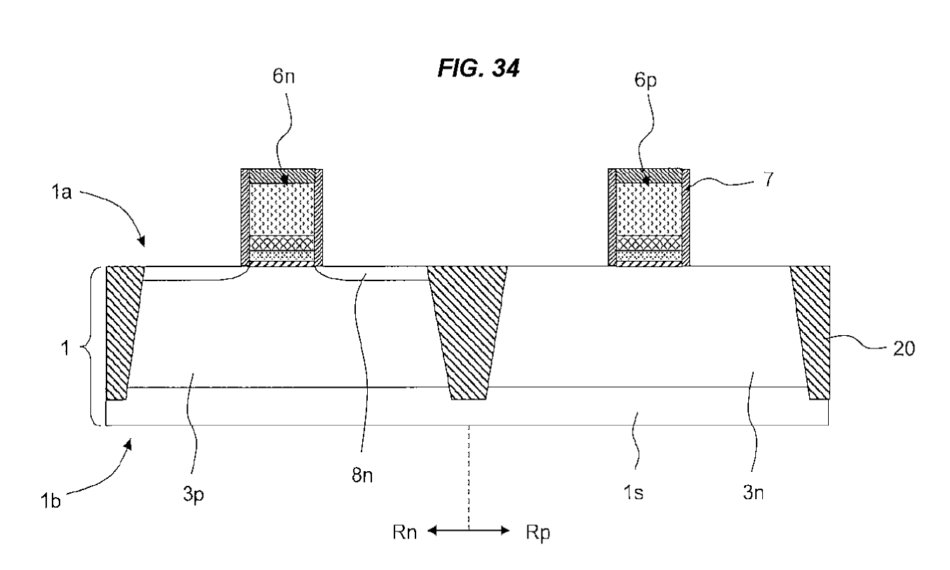

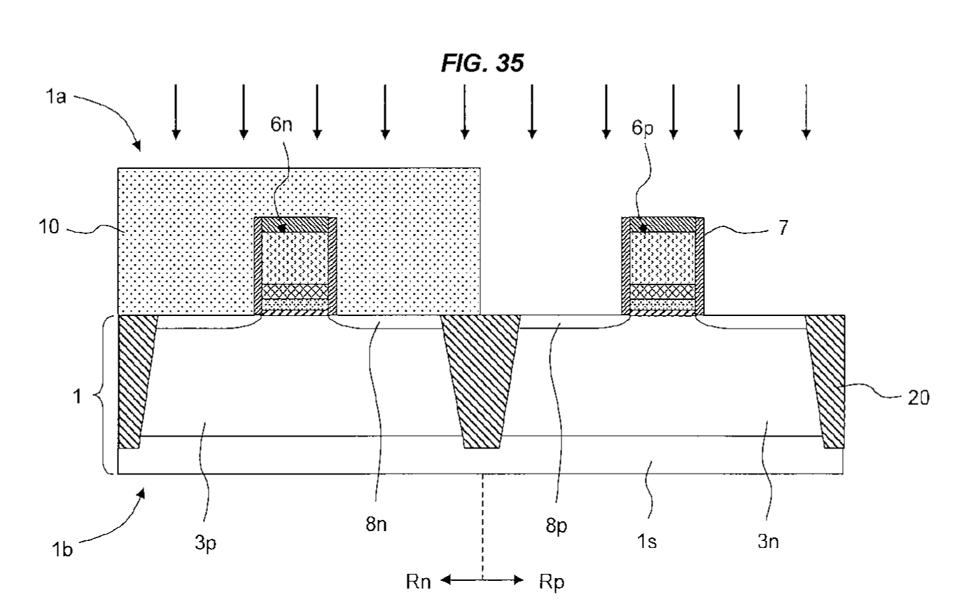

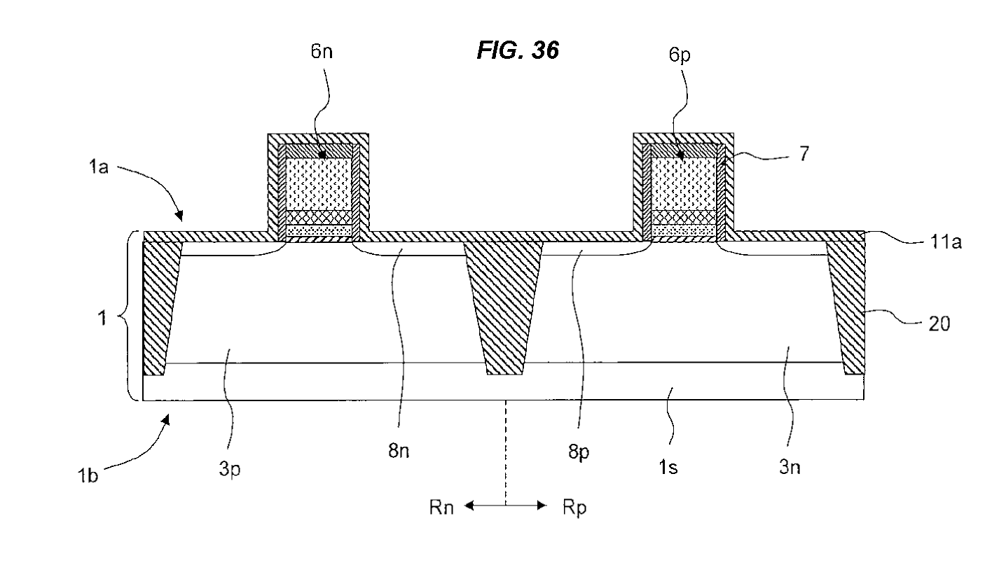

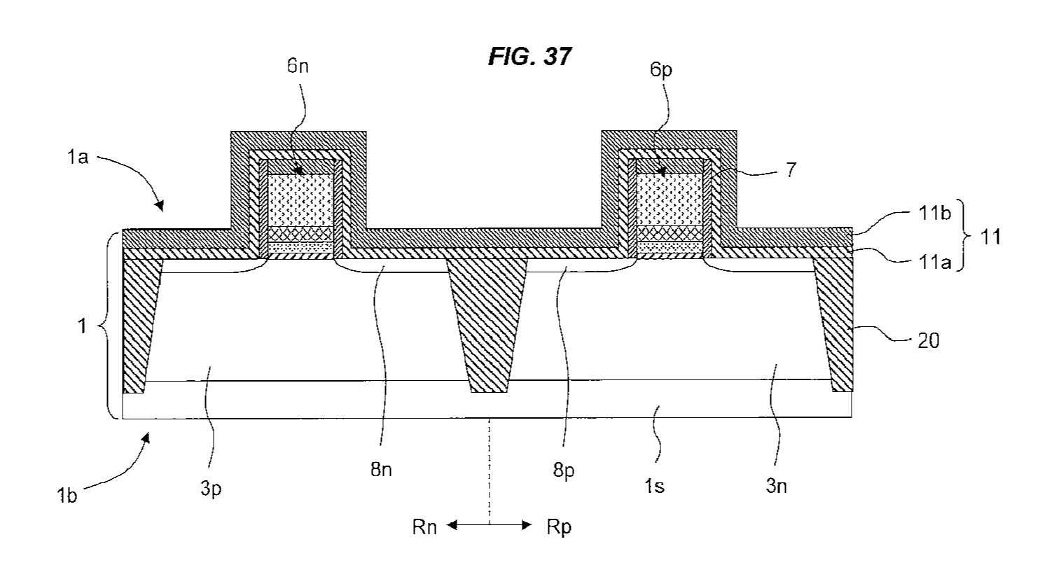

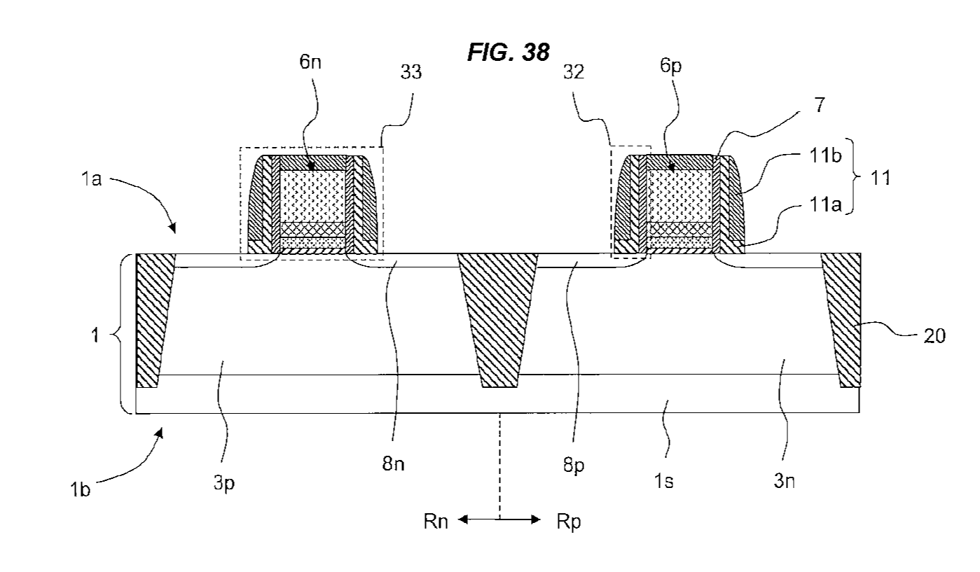

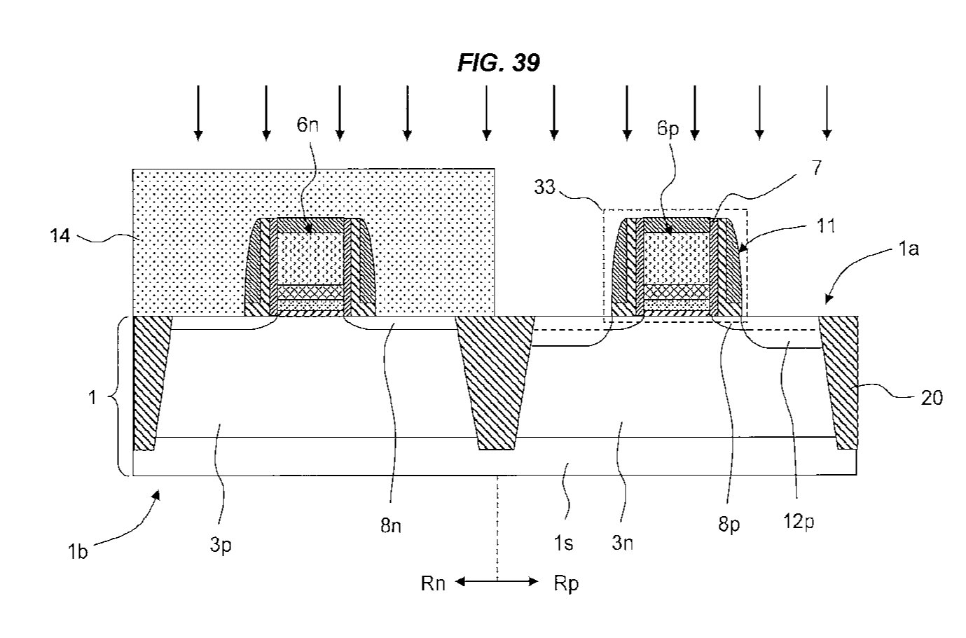

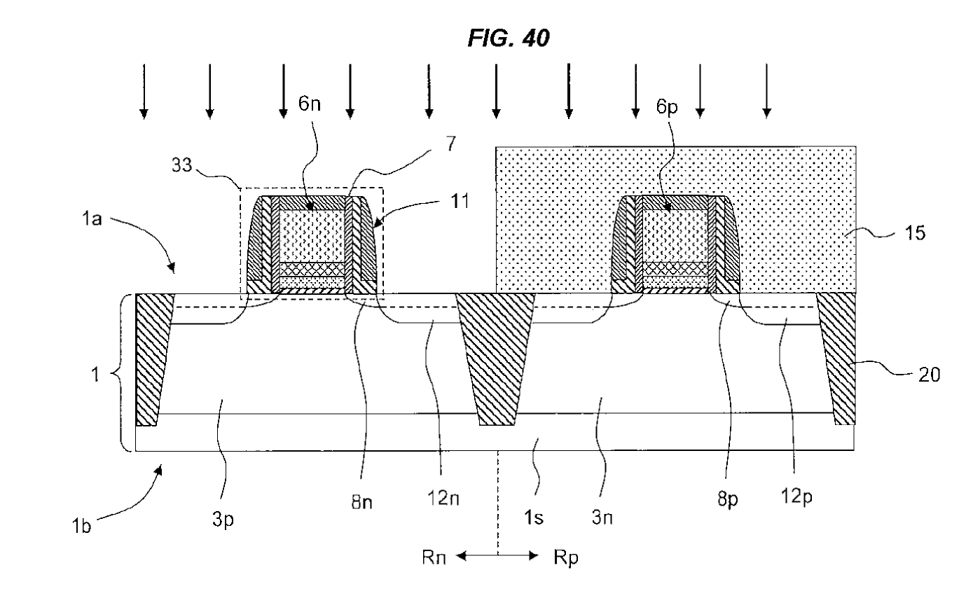

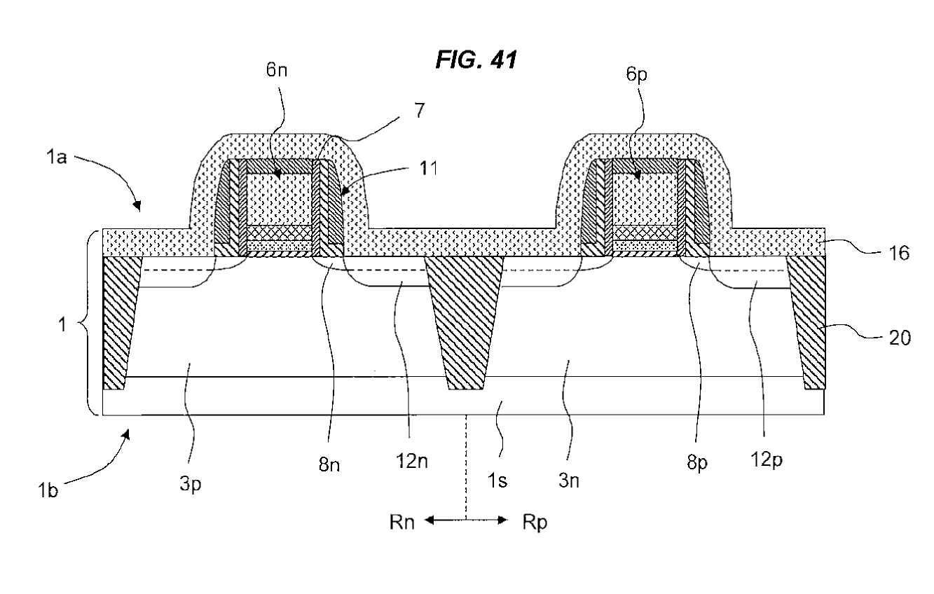

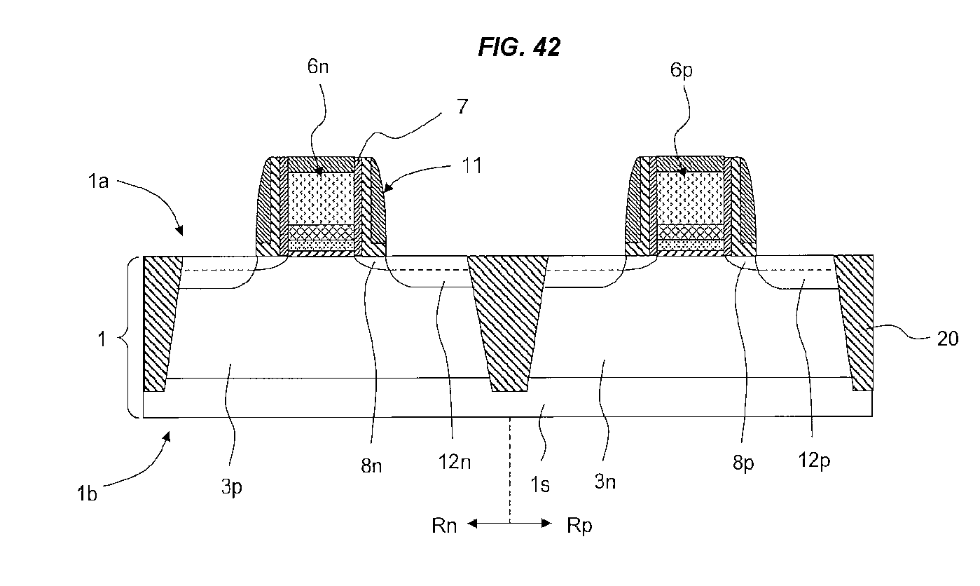

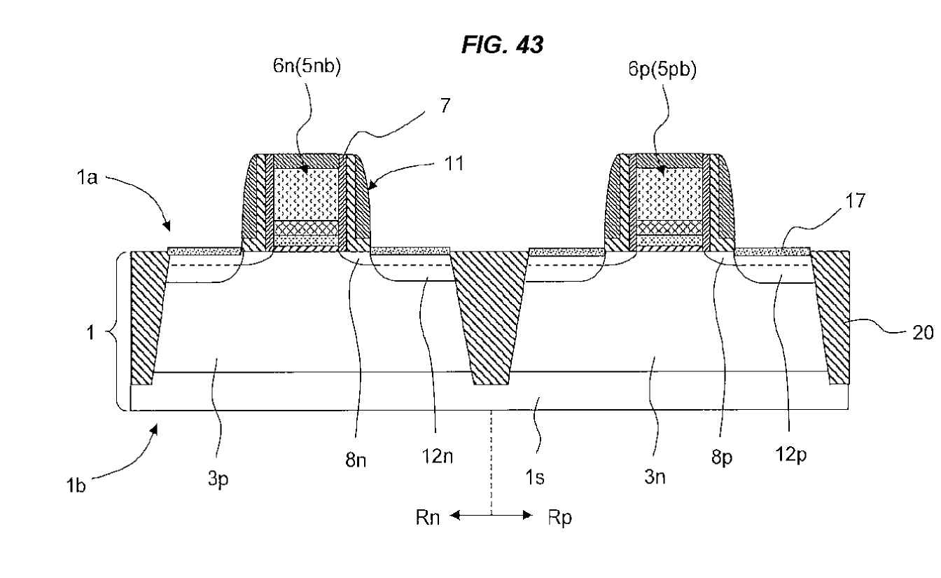

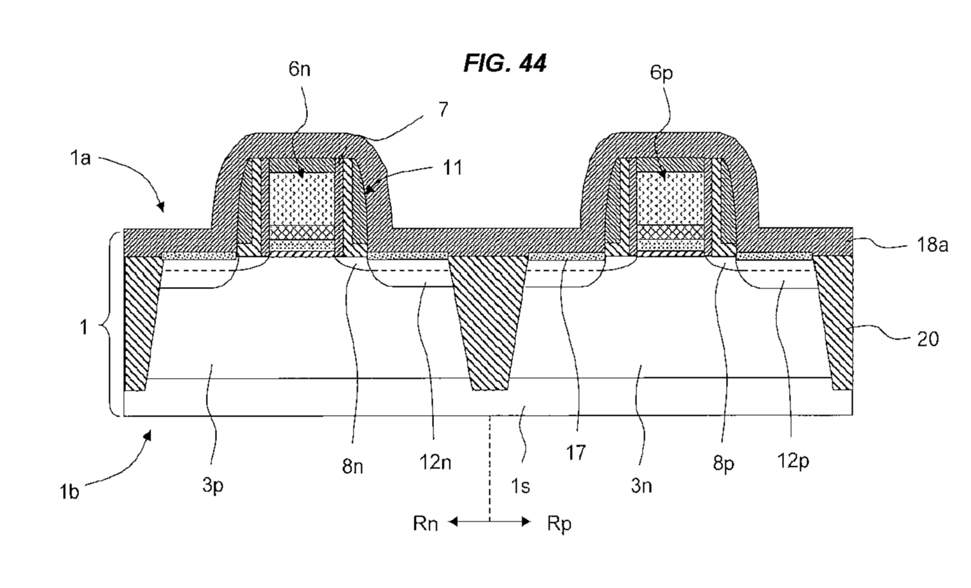

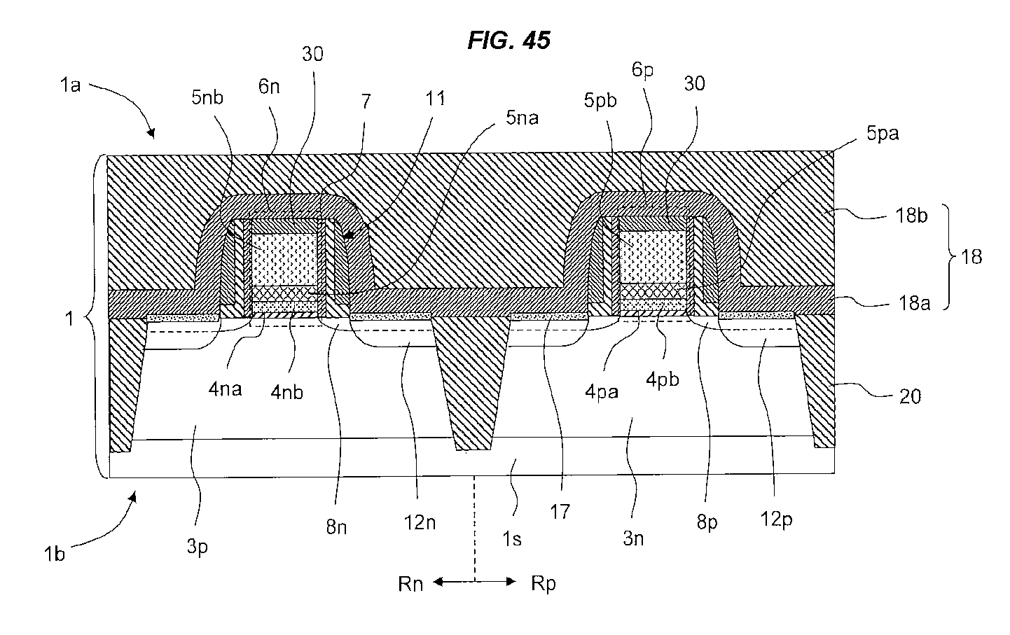

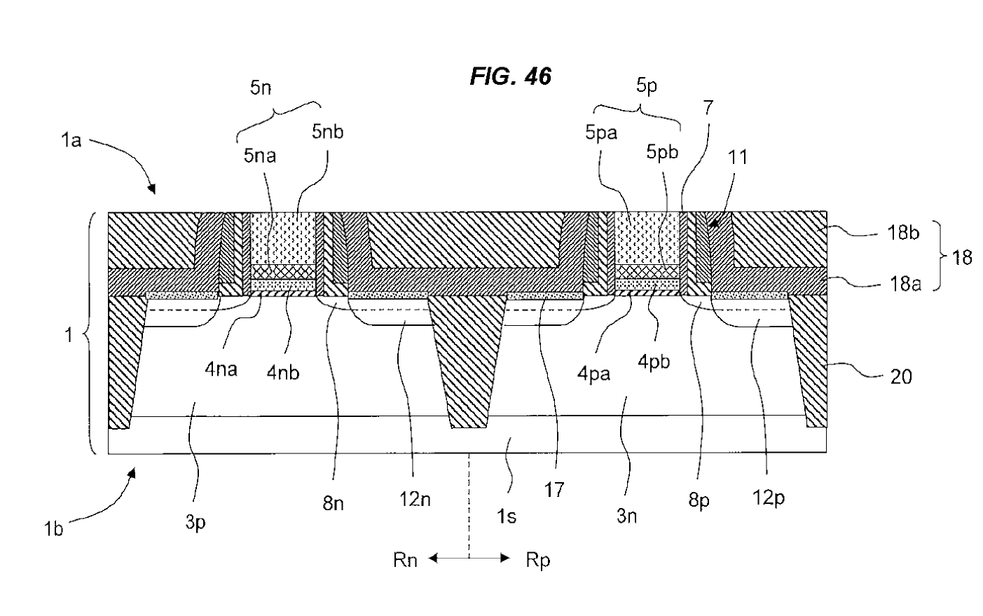

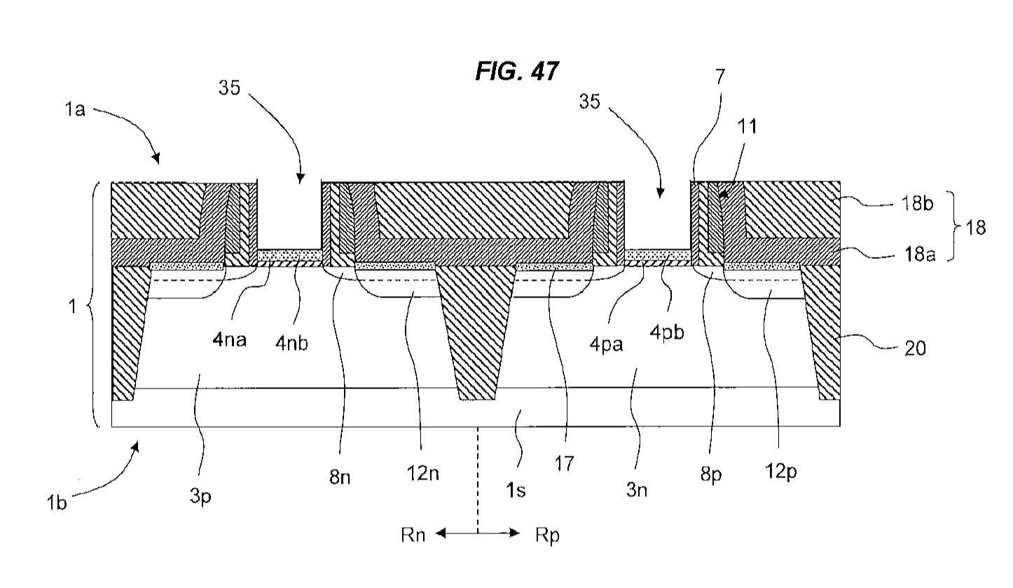

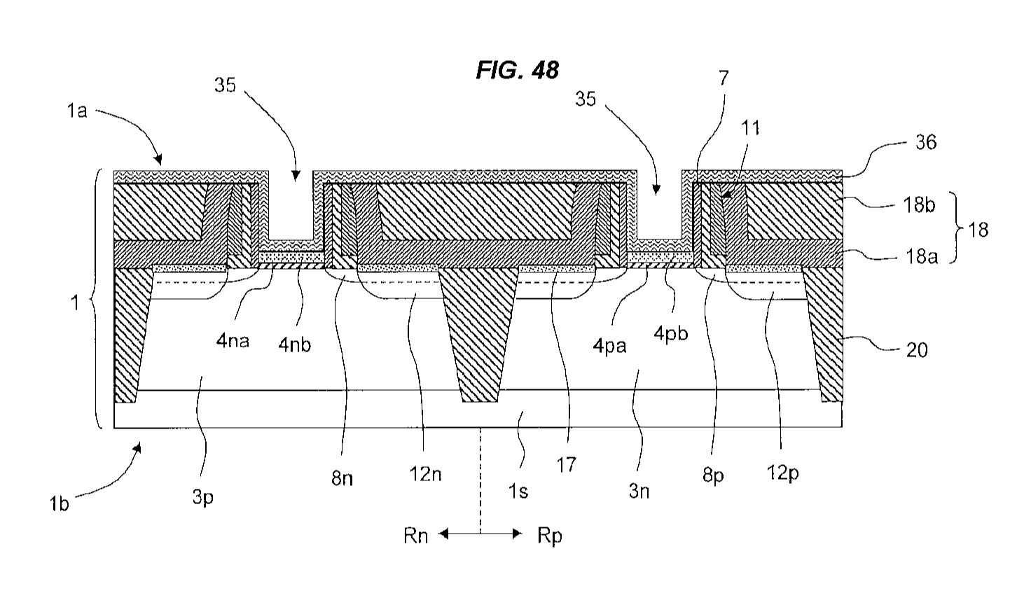

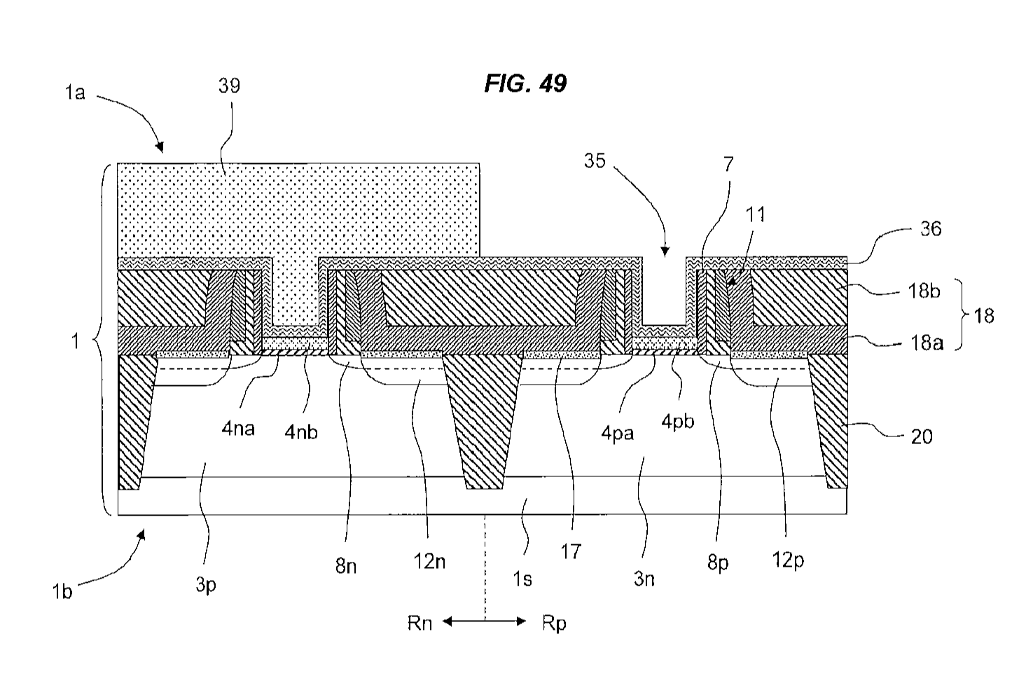

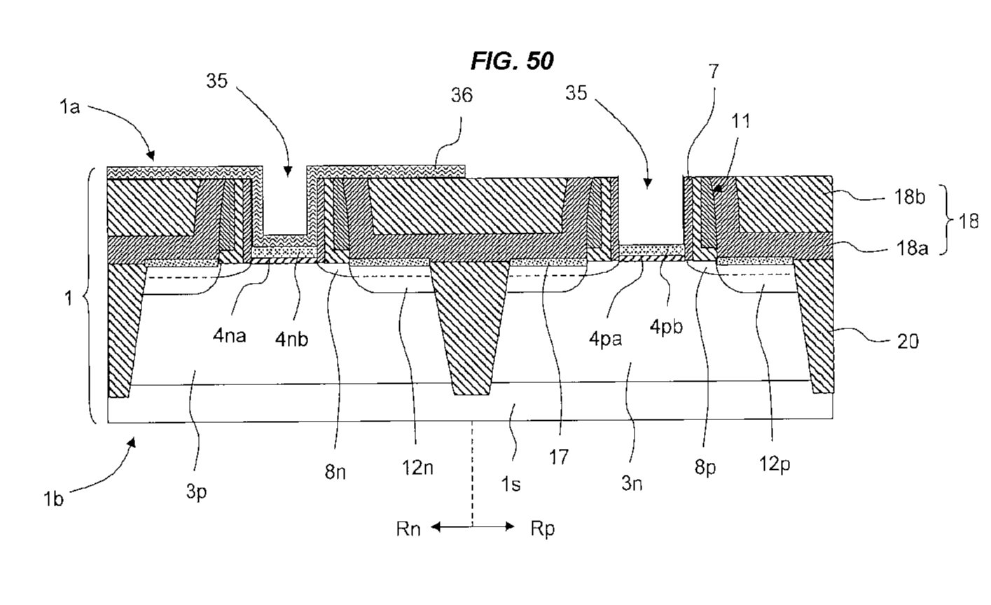

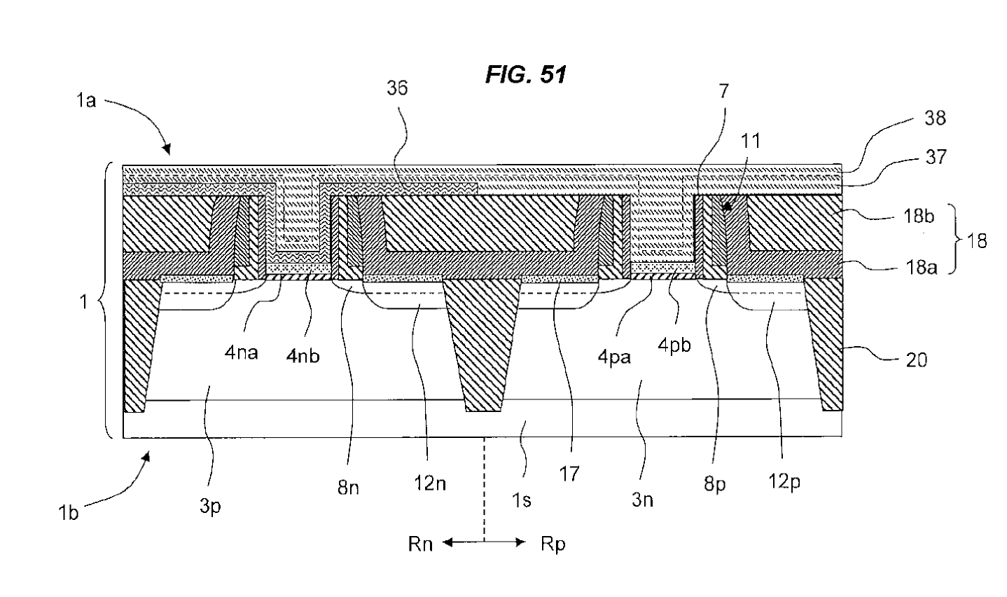

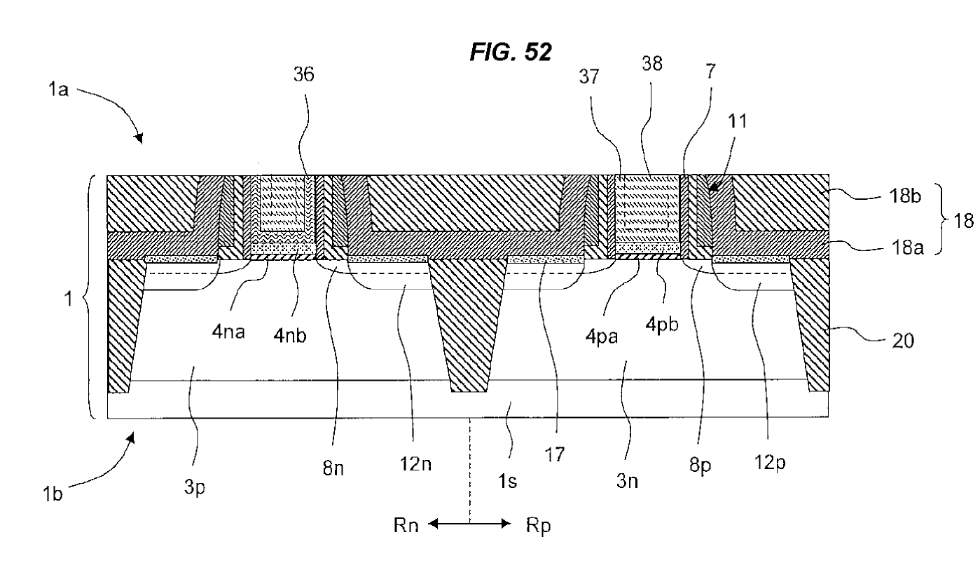

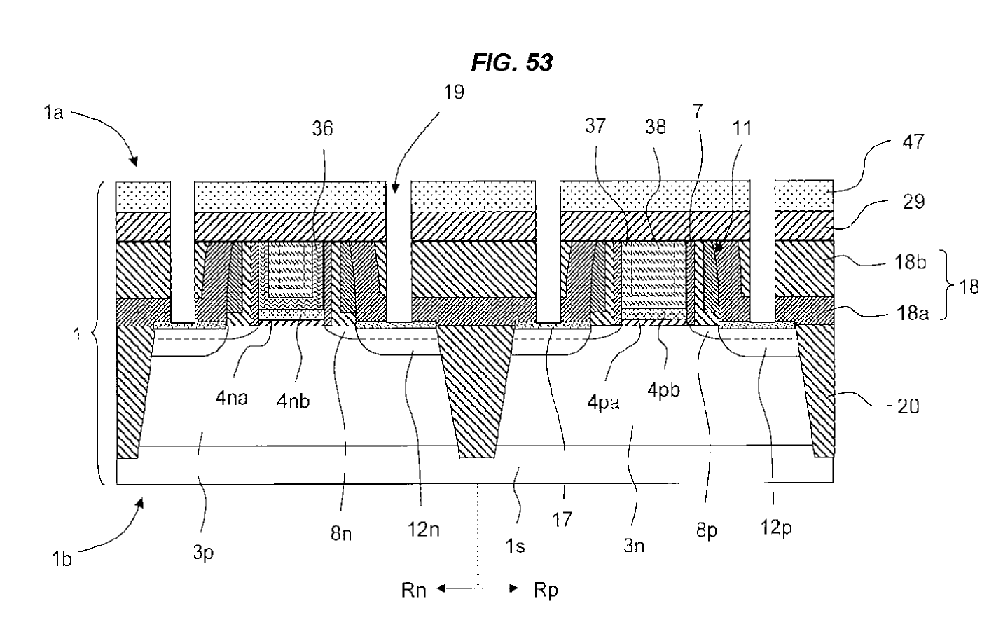

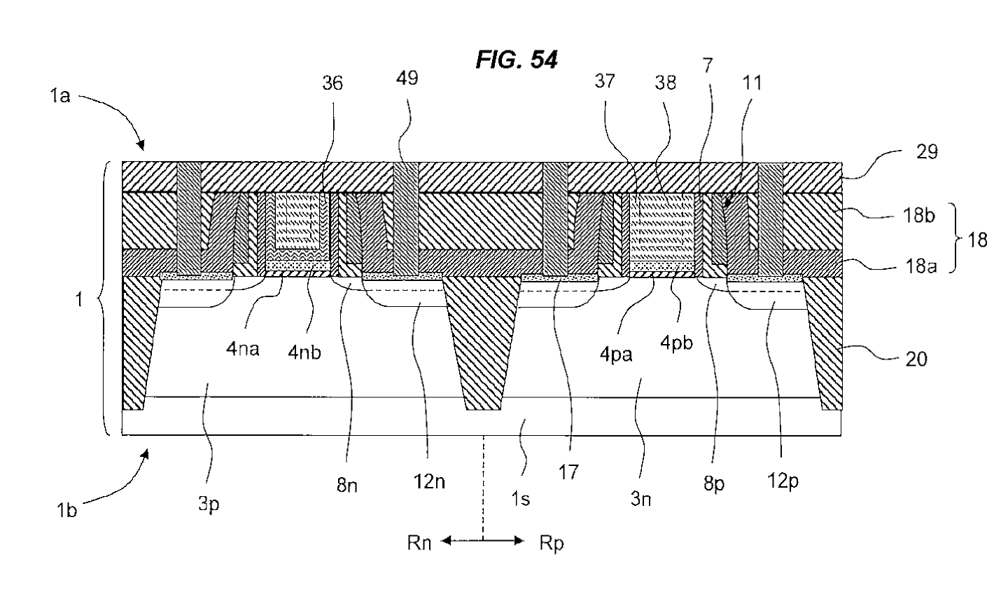

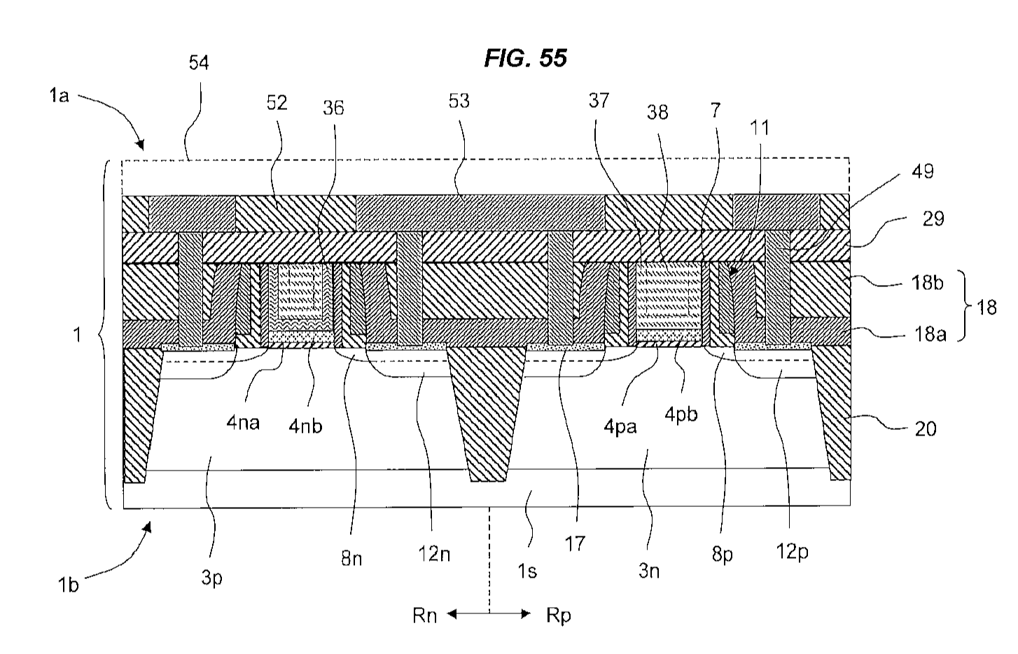

FIG. 31 is a partial cross-sectional view of a wafer (at the time of completing fabrication of the gate stack) for explaining the CMIS process flow in the manufacturing method of a semiconductor integrated circuit device in accordance with the embodiment of Part 2 of the present application. FIG. 32 is a partial cross-sectional view of a wafer (at the time of forming an offset spacer silicon nitride film) for explaining the CMIS process flow in the manufacturing method of a semiconductor integrated circuit device in accordance with the embodiment of Part 2 of the present application. FIG. 33 is a partial cross-sectional view of a wafer (at the time of introducing an N-type source/drain extension region) for explaining the CMIS process flow in the manufacturing method of a semiconductor integrated circuit device in accordance with the embodiment of Part 2 of the present application. FIG. 34 is a partial cross-sectional view of a wafer (at the time of etching back the offset spacer silicon nitride film) for explaining the CMIS process flow in the manufacturing method of a semiconductor integrated circuit device in accordance with the embodiment of Part 2 of the present application. FIG. 35 is a partial cross-sectional view of a wafer (at the time of introducing a P-type source/drain extension region) for explaining the CMIS process flow in the manufacturing method of a semiconductor integrated circuit device in accordance with the embodiment of Part 2 of the present application. FIG. 36 is a partial cross-sectional view of a wafer (at the time of forming a side wall silicon oxide film) for explaining the CMIS process flow in the manufacturing method of a semiconductor integrated circuit device in accordance with the embodiment of Part 2 of the present application. FIG. 37 is a partial cross-sectional view of a wafer (at the time of forming a side wall silicon nitride film) for explaining the CMIS process flow in the manufacturing method of a semiconductor integrated circuit device in accordance with the embodiment of Part 2 of the present application. FIG. 38 is a partial cross-sectional view of a wafer (at the time of etching back the side wall insulation film) for explaining the CMIS process flow in the manufacturing method of a semiconductor integrated circuit device in accordance with the embodiment of Part 2 of the present application. FIG. 39 is a partial cross-sectional view of a wafer (at the time of introducing a P-type high density source/drain region) for explaining the CMIS process flow in the manufacturing method of a semiconductor integrated circuit device in accordance with the embodiment of Part 2 of the present application. FIG. 40 is a partial cross-sectional view of a wafer (at the time of introducing an N-type high density source/drain region) for explaining the CMIS process flow in the manufacturing method of a semiconductor integrated circuit device in accordance with the embodiment of Part 2 of the present application. FIG. 41 is a partial cross sectional view of a wafer (at the time of forming an oxygen absorption film and activation annealing) for explaining the CMIS process flow in the manufacturing method of a semiconductor integrated circuit device of the embodiment of Part 2 of the present application. FIG. 42 is a partial cross-sectional view of a wafer (at the time of removing the oxygen absorption film) for explaining the CMIS process flow in the manufacturing method of a semiconductor integrated circuit device in accordance with the embodiment of Part 2 of the present application. FIG. 43 is a partial cross-sectional view of a wafer (at the time of completing the silicidation) for explaining the CMIS process flow in the manufacturing method of a semiconductor integrated circuit device in accordance with the embodiment of Part 2 of the present application. FIG. 44 is a partial cross-sectional view of a wafer (at the time of forming a CESL) for explaining the CMIS process flow in the manufacturing method of a semiconductor integrated circuit device in accordance with the embodiment of Part 2 of the present application. FIG. 45 is a partial cross-sectional view of a wafer (at the time of forming a silicon oxide-based premetal insulation film) for explaining the CMIS process flow in the manufacturing method of a semiconductor integrated circuit device in accordance with the embodiment of Part 2 of the present application. FIG. 46 is a partial cross-sectional view of a wafer (at the time of completing the surface planarizing process before removing the dummy gate electrode) for explaining the CMIS process flow in the manufacturing method of a semiconductor integrated circuit device in accordance with the embodiment of Part 2 of the present application. FIG. 47 is a partial cross-sectional view of a wafer (at the time of completing the dummy gate electrode removal process) for explaining the CMIS process flow in the manufacturing method of a semiconductor integrated circuit device in accordance with the embodiment of Part 2 of the present application. FIG. 48 is a partial cross-sectional view of a wafer (at the time of completing the NMIS work function metal film formation process) for explaining the CMIS process flow in the manufacturing method of a semiconductor integrated circuit device in accordance with the embodiment of Part 2 of the present application. FIG. 49 is a partial cross-sectional view of a wafer (at the time of completing the resist film patterning process for removing the NMIS work function metal film) for explaining the CMIS process flow in the manufacturing method of a semiconductor integrated circuit device in accordance with the embodiment of Part 2 of the present application. FIG. 50 is a partial cross-sectional view of a wafer (at the time of completing the NMIS work function metal film patterning process) for explaining the CMIS process flow in the manufacturing method of a semiconductor integrated circuit device in accordance with the embodiment of Part 2 of the present application. FIG. 51 is a partial cross-sectional view of a wafer (at the time of completing the PMIS work function metal film formation and gate electrode embedding groove filling metal film formation process) for explaining the CMIS process flow in the manufacturing method of a semiconductor integrated circuit device in accordance with the embodiment of Part 2 of the present application. FIG. 52 is a partial cross-sectional view of a wafer (at the time of completing the work function metal CMP process) for explaining the CMIS process flow in the manufacturing method of a semiconductor integrated circuit device in accordance with the embodiment of Part 2 of the present application. FIG. 53 is a partial cross-sectional view of a wafer (at the time of completing the contact hole formation) for explaining the CMIS process flow in the manufacturing method of a semiconductor integrated circuit device in accordance with the embodiment of Part 2 of the present application. FIG. 54 is a partial cross-sectional view of a wafer (at the time of completing the tungsten plug embedding) for explaining the CMIS process flow in the manufacturing method of a semiconductor integrated circuit device in accordance with the embodiment of Part 2 of the present application. FIG. 55 is a partial cross-sectional view of a wafer (at the time of completing the multilayer wiring) for explaining the CMIS process flow in the manufacturing method of a semiconductor integrated circuit device in accordance with the embodiment of Part 2 of the present application. Based on these drawings, a process flow (Gate Last process) in the manufacturing method of a semiconductor integrated circuit device in accordance with to an embodiment of Part 2 of the present application will be explained.

As shown in FIG. 31, the P-well region 3p and the N-well region 3n separated by the shallow trench isolation (STI) region (oxide element isolation region) 20 are provided on the device surface (first main surface) 1a side (the other side of the back surface 1b) of the substrate is (with a specific resistance of about 1 to 10 Ωcm) of the P-type single crystal silicon wafer 1. The part provided with the P-well region 3p corresponds to the N-type MISFET region Rn, and the part provided with the N-well region 3n corresponds to the P-type MISFET region Rp. A gate stack 6n of the N-type MISFET is provided over the device surface 1a of the N-type MISFET region Rn, and the gate stack 6p of the P-type MISFET is provided over the device surface 1a of the P-type MISFET region Rp. Formation of the STI region (oxide element isolation region) 20 is performed by normal dry etching, embedding of a silicon oxide-based insulation film by chemical vapor deposition (CVD), a planarizing process by chemical mechanical deposition (CMP), and the like.

The dummy gate stack 6n includes, in the order from the bottom, the gate insulation film 4n and the gate electrode 5n. The gate insulation film 4n includes, in the order from the bottom, the interfacial layer gate insulation film 4na (about 1 nm thick) such as a silicon oxide-based film (including a silicon oxynitride film), and the High-k Gate insulation film 4nb (about 1.5 nm thick) such as a hafnium oxide-based insulation film added with lanthanum or the like. The gate electrode 5n includes, in the order from the bottom, the metal gate electrode 5na including titanium nitride (about 10 nm thick), and the poly-Si gate electrode 5nb (about 50 nm thick) (the uppermost layer is the gate fabrication hardmask film 10 such as a silicon nitride film formed by CVD). The dummy gate stack 6p includes, in the order from the bottom, the gate insulation film 4p, and the gate electrode 5p. The gate insulation film 4p includes, in the order from the bottom, the interfacial gate insulation film 4pa (about 1 nm thick) such as a silicon oxide-based film (including a silicon oxynitride film), and the High-k Gate insulation film 4pb (about 1.5 nm thick) such as a hafnium oxide-based insulation film added with aluminum. The gate electrode 5p includes, in the order from the bottom, the metal gate electrode 5pa including titanium nitride (about 10 nm thick), and the poly-Si gate electrode 5pb (about 50 nm thick) (as described above, the uppermost layer is the gate fabrication hardmask film 10 such as a silicon nitride film formed by CVD). Formation of the dummy gate stacks 6n and 6p is performed by thermal oxidation, atomic layer deposition (ALD), sputtering film formation, CVD, anisotropic dry etching and the like.

Next, as shown in FIG. 32, the offset spacer silicon nitride film 7 (about 10 nm thick) is formed by CVD on almost entire surface of the device surface 1a of the wafer 1.

Next, as shown in FIG. 33, the N-type source/drain extension region 8n is introduced on the semiconductor substrate surface at both sides of the dummy gate stack 6n by ion implantation in a state of covering the P-type MISFET region Rp with the N-type source/drain extension region introduction resist film 9 by normal lithography. Preferred ion implantation conditions can be exemplified as follows: Ion type: As, implanting energy: 1 KeV to 10 KeV, dose amount: 1×10¹⁵/cm² to 9×10¹⁵/cm²; and ion type: C, implanting energy: 1 KeV to 5 KeV, dose amount: 4×10¹⁴/cm² to 9×10¹⁴/cm².

Subsequently, the resist film 9 which has become unnecessary is removed by asking or the like.

Next, as shown in FIG. 34, the silicon nitride-based offset spacer 7 is formed by anisotropic dry etching.

Next, as shown in FIG. 35, the P-type source/drain extension region is introduced on the semiconductor substrate surface at both sides of the dummy gate stack 6p by ion implantation in a state of covering the N-type MISFET region Rn with the P-type source/drain extension region introduction resist film 10 by normal lithography. Ion implantation conditions can be exemplified as follows: Ion type: BF2, implanting energy: 1 KeV to 5 KeV, dose amount: 1×10¹⁵/cm² to 8×10¹⁵/cm²; and ion type: C, implanting energy: 1 KeV to 5 KeV, dose amount: 4×10¹⁴/cm² to 9×10¹⁴/cm².

Subsequently, the resist film 10 which has become unnecessary is removed by asking or the like.

Next, as shown in FIG. 36, the side wall silicon oxide-based film 11a (about 10 nm thick) is formed by CVD on almost entire surface of the device surface 1a of the wafer 1.

Next, as shown in FIG. 37, the side wall silicon nitride film 11b (about 20 nm thick) is formed by CVD on almost entire surface of the device surface 1a of the wafer 1. The side wall insulation film 11 includes the side wall silicon oxide film 11a and the side wall silicon nitride film 11b.

Next, as shown in FIG. 38, the side wall 11 including the silicon oxide-based side wall 11a and the silicon nitride-based side wall 11b is formed by anisotropic dry etching. The structure including the silicon nitride-based offset spacer 7 and the side wall insulation film 11 is referred to as a gate side surface structure 32. In addition, the structure including the dummy gate stacks (6n and 6p) and the gate side surface structure 32 is referred to as a gate structure 33.

Next, as shown in FIG. 39, the P-type high density source/drain region 12p is introduced on the semiconductor substrate surface at both sides of the gate structure 33 of the P-type MISFET by ion implantation in a state of covering the N-type MISFET region Rn with the P-type high density source/drain region introduction resist film 14 by normal lithography. Ion implantation conditions can be

exemplified as follows: Ion type: B, implanting energy: 0.5 KeV to 20 KeV, dose amount: 1×10¹⁵/cm² to 8×10¹⁵/cm².

Subsequently, the resist film 14 which has become unnecessary is removed by asking or the like.

Next, as shown in FIG. 40, the N-type high density source/drain region 12n is introduced on the semiconductor substrate surface at both sides of the gate structure 33 of N-type MISFET by ion implantation in a state of covering the P-type MISFET region Rp with the N-type high density source/drain region introduction resist film 15 by normal lithography. Ion implantation conditions can be exemplified as follows: Ion type: As, implanting energy: 2 KeV to 40 KeV, dose amount: 8×10¹⁴/cm² to 4×10¹⁵/cm²; and ion type: P, implanting energy: 10 KeV to 80 KeV, dose amount: 1×10¹³/cm² to 8×10¹³/cm².

Subsequently, the resist film 15 which has become unnecessary is removed by ashing or the like.

Next, as shown in FIG. 41, the oxygen absorption film 16 such as an amorphous Si film (about 30 nm thick) is formed by CVD on almost entire surface of the device surface 1a of the wafer 1. Preferred temperatures for forming the oxygen absorption film 16 can be exemplified such as 400 to 500 degrees Celsius (preferred film-forming temperatures can be exemplified such as 450 to 650 degrees Celsius if the oxygen absorption film 16 is a polysilicon film). It is preferred to form the second silicon oxide-based insulation film (the thin-film silicon oxide film 28 with a thickness of about 1 nm (referred to as an “ashing silicon oxide film”)) on the silicon surface of the device surface 1a of the wafer 1 by the plasma oxidation process in the oxygen atmosphere (ashing oxidation process), before forming the oxygen absorption film 16 (see FIGS. 29 and 30). This is performed for preventing damage to the silicon surface of the device surface 1a of the underlying wafer 1 when the oxygen absorption film 16 is removed.

Subsequently, high temperature anneal is performed to activate the injected impurities with the oxygen absorption film 16 having been formed. Preferred high temperature anneal can be exemplified such as a combination of spike RTA (about 1 second at about 1000 degrees Celsius) and laser spike anneal (LSA). The preferred condition of LSA can be exemplified such as a unit spike at about 1200 degrees Celsius.

The oxygen absorption film 16 may be a poly-Si film (about 30 nm thick, for example). However, because the oxygen absorption film 16 also acts as a stress applying film, an amorphous Si film is more advantageous to the stress applying operation.

Next, as shown in FIG. 42, the whole oxygen absorption film 16 is removed. The oxygen absorption process is completed by this. Removal of the oxygen absorption film is performed using an alkali-based etchant such as ammonia/hydrogen peroxide solution, using an ashing silicon oxide film as an etch-stop film. The ashing silicon oxide film is removed by subsequent cleaning using hydrofluoric acid-based cleaning liquid.

Next, as shown in FIG. 43, the nickel silicide-based silicide film 17 (e.g., Ni Pt silicide) is formed over the N-type high density source/drain region 12n, and the P-type high density source/drain region 12p as necessary by a normal salicide process.

Next, as shown in FIG. 44, the contact etch-stop silicon nitride film 18a (about 25 nm thick) is formed on almost entire surface of the device surface 1a of the wafer 1 by CVD.

Next, as shown in FIG. 45, the contact etch-stop silicon nitride film 18a, together with the silicon oxide-based premetal insulation film 18b (usually this film is thicker than the contact etch-stop silicon nitride film 18a, being about 200 nm thick) constituting a premetal insulation film 18, is formed on almost entire surface of the device surface 1a of the wafer 1 by CVD.

Next, as shown in FIG. 46, chemical mechanical polishing (CMP) is performed on the device surface 1a of the wafer 1 and terminated at the poly-Si dummy gate electrodes 5nb and 5pb.

Next, as shown in FIG. 47, a gate electrode embedding groove 35 is formed by etching and removing the dummy gate electrodes 5n and 5p (FIG. 46). Removal of the poly-Si dummy gate electrodes 5nb and 5pb is performed by dry etching using gas such as O₂/CF₄, whereas removal of the metal dummy gate electrodes 5na and 5pa is performed by wet etching using HCl/H₂O₂-based chemical liquid.

Next, as shown in FIG. 48, an NMIS work function metal film 36 (TiN film) having a thickness of about 2 nm is formed on the entire surface on the device surface 1a side of the wafer 1 by sputtering film formation.

Next, as shown in FIG. 49, an NMIS work function metal film removal resist film 39 is patterned by normal lithography.

Next, as shown in FIG. 50, the NMIS work function metal film 36 of the unnecessary part is removed by wet etching, for example, using the patterned NMIS work function metal film removal resist film 39 as a mask. Subsequently, the NMIS work function metal film removal resist film 39 which has become unnecessary is entirely removed. HCl/H2O2-based chemical liquid can be exemplified as the removal liquid of the NMIS work function metal film 36.

Next, as shown in FIG. 51, a PMIS work function metal film 37 (TiAlN film) having a thickness of about 1.5 nm is formed on the entire surface on the device surface 1a side of the wafer 1 by sputtering film formation. Subsequently, agate electrode embedding groove filling metal film 38 (AlTi film) having a thickness of about 20 nm is formed on almost entire surface over the PMIS work function metal film 37 by sputtering film formation.

Next, as shown in FIG. 52, the PMIS work function metal film 37 and the gate electrode embedding groove filling metal film 38 outside the gate electrode embedding groove 35 are removed using a metal CMP.

Next, as shown in FIG. 53, a premetal additional stacking insulation film 29 such as a silicon oxide-based film is formed on the entire surface on the device surface 1a side of the wafer 1. Subsequently, a contact hole forming resist film 47 is formed on almost entire surface over the premetal additional stacking insulation film 29 by coating or the like. Subsequently, the resist film 47 is patterned by normal lithography (ArF lithography). The contact hole 19 is sequentially opened in the premetal additional stacking insulation film 29, the silicon oxide-based premetal insulation film 18b, and the contact etch-stop silicon nitride film 18a by anisotropic dry etching using the patterned resist film 47 as a mask. Subsequently, the resist film 47 which has become unnecessary is removed by asking or the like.

Next, as shown in FIG. 54, a tungsten plug 49 is embedded in the contact hole 19.

Next, as shown in FIG. 55, a silicon oxide film-based first layer wiring insulation film 52 is formed over the premetal additional stacking insulation film 29 to form a first layer embedded wiring 53 such as a copper-based embedded wiring (single damascene wiring) (an aluminum-based unembedded wiring or a mixed wiring in which embedded wiring and an unembedded wiring are applied to separate layers may be applied). After that, a similar process is repeated to form an upper multilayer wiring layer (a dual damascene wiring), a final passivation film, a bonding pad or the like. Subsequently, individual chips 2 are formed via a wafer test process, aback grinding process, a dicing process and the like, and packaged as necessary into the final device.

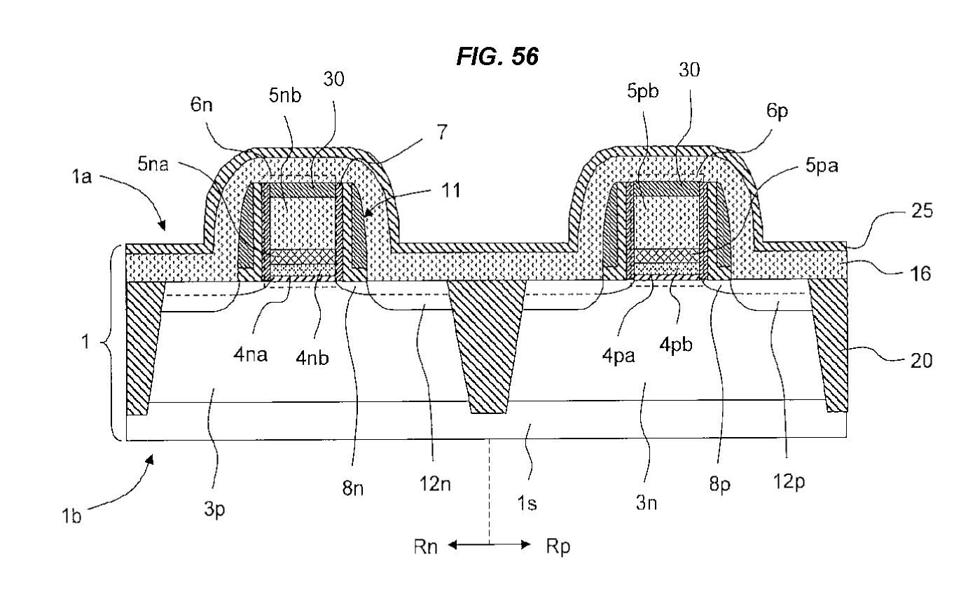

3. Explanation of a process flow (gate-last process) in an exemplary variation of the manufacturing method of a semiconductor integrated circuit device in accordance with the embodiment of Part 2 of the present application (mainly, FIGS. 56 to 59)

The example of this section is an exemplary variation 1 of the oxygen absorption process of FIGS. 41 to 42 (referred to as “additional stressor overcoat approach”) of Section 2, above which a silicon nitride-based stress applying film such as a silicon nitride film is added as an additional stress applying film to increase the effect of applying stress which is a side effect of the oxygen absorption film 16. Therefore, with the explanation for FIGS. 31 to 55 being completely the same, only different parts. FIGS. 41 and 42 will be explained below.

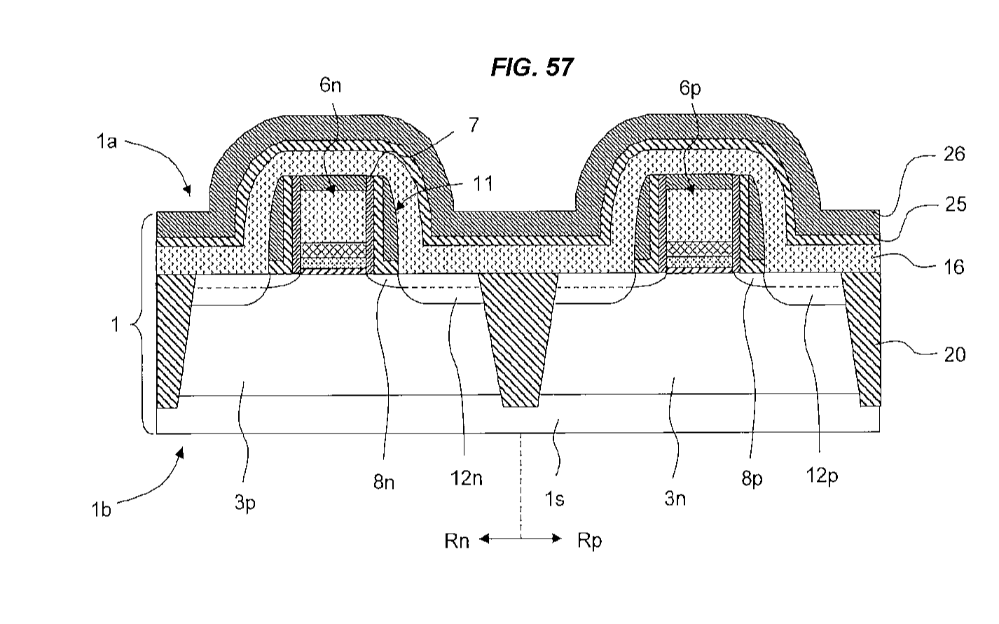

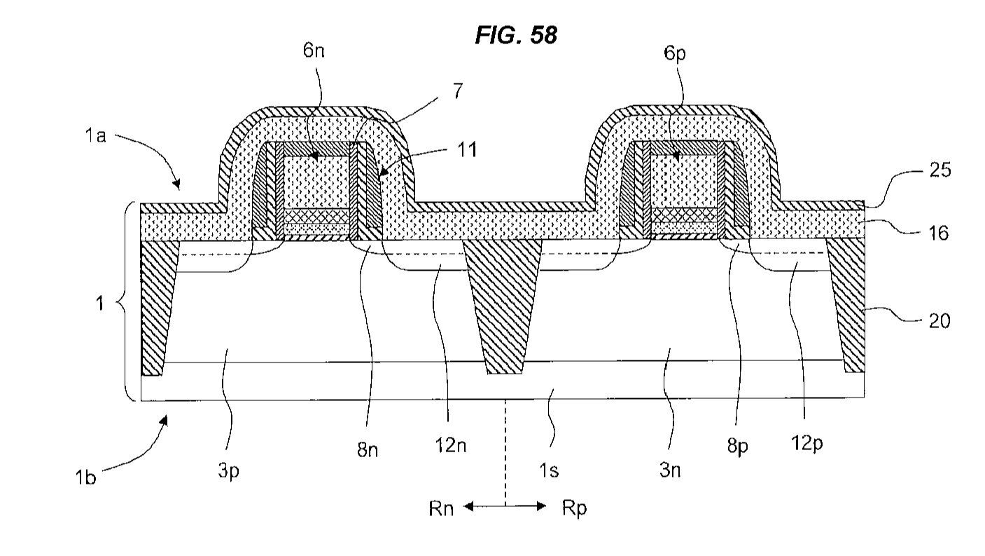

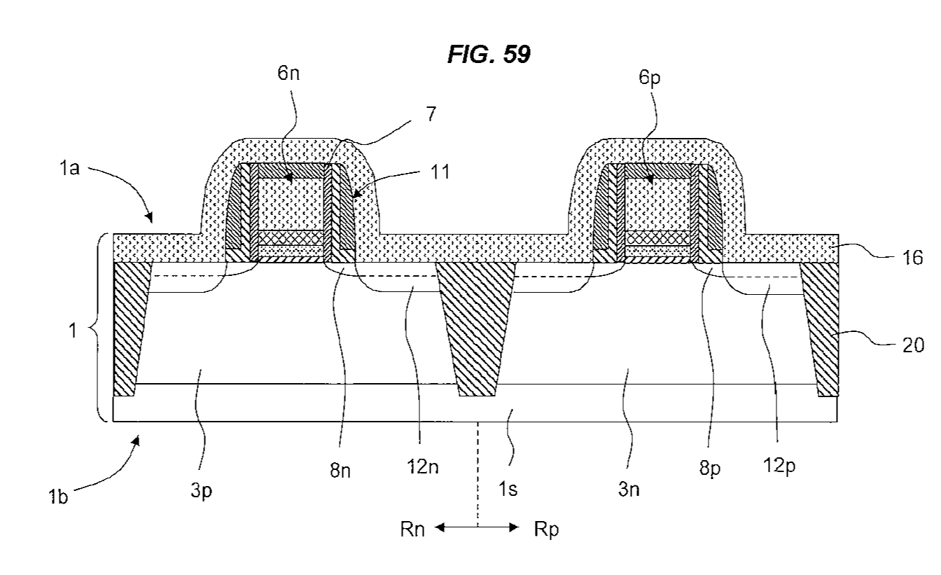

FIG. 56 is a partial cross-sectional view of a wafer (at the time of forming an intermediate silicon oxide-based thin film) for explaining a process flow in an exemplary variation of the manufacturing method of a semiconductor integrated circuit device in accordance with an embodiment of the present application. FIG. 57 is a partial cross-sectional view of a wafer (at the time of forming a silicon nitride-based stressor film and activation annealing) for explaining a process flow in an exemplary variation of the manufacturing method of a semiconductor integrated circuit device in accordance with an embodiment of the present application. FIG. 58 is a partial cross-sectional view of a wafer (at the time of removing the silicon nitride-based stressor film) for explaining a process flow in an exemplary variation of the manufacturing method of a semiconductor integrated circuit device in accordance with an embodiment of the present application. FIG. 59 is a partial cross-sectional view of a wafer (at the time of removing the intermediate silicon oxide-based thin film) for explaining a process flow in an exemplary variation of the manufacturing method of a semiconductor integrated circuit device in accordance with an embodiment of the present application. Based on these drawings, a process flow (gate-last process) in the exemplary variation of the manufacturing method of a semiconductor integrated circuit device in accordance with the embodiment of Part 2 of the present application will be explained.

As shown in FIG. 56, following FIG. 41, the relatively thin (thinner than the oxygen absorption film 16) intermediate silicon oxide-based thin film 25 (about 10 nm thick) such as a silicon oxide film (a first silicon oxide-based insulation film) is formed on almost entire surface over the oxygen absorption film 16 (oxygen absorption amorphous Si film or oxygen absorption poly-Si film) by CVD.

Next, as shown in FIG. 57, the relatively thick (thicker than the oxygen absorption film 16) silicon nitride-based stressor film 26 (about 30 nm thick) such as a silicon nitride film is formed on almost entire surface over the intermediate silicon oxide-based film 25 by CVD.

Subsequently, high temperature anneal is performed to activate the injected impurities, with the oxygen absorption film 16, the intermediate silicon oxide-based thin film 25, and the silicon nitride-based stressor film 26 having been formed.

Next, as shown in FIG. 58, the silicon nitride-based stressor film 26 is entirely removed. Removal of the silicon nitride-based stressor film 26 is performed by wet treatment using heated phosphoric acid.

Next, as shown in FIG. 59, the intermediate silicon oxide-based thin film 25 is entirely removed. Removal of the intermediate silicon oxide-based thin film 25 is performed using hydrofluoric-acid-based silicon film etchant solution.

Subsequently, as described above, removing the oxygen absorption film 16 from all over the surface results in the state of FIG. 42. Removal of the oxygen absorption film 16 is performed using alkali etchant solution such as ammonia/hydrogen peroxide solution, using the ashing silicon oxide film as an etch-stop film. The ashing silicon oxide film is removed by subsequent cleaning using hydrofluoric acid-based cleaning liquid.

Subsequently, the previously explained processes of FIG. 42 and later are performed.

4. Explanation of Application to Another Gate-Last Approach

Although removal of all the dummy gate electrodes 5n and 5p has been shown in the example of Sections 2 and 3 (High-k First/Metal gate-last approach), the removal may also proceed downward from the top as far as the poly-Si dummy gate electrodes 5nb and 5pb, leaving the metal gate electrodes 5na and Spa and lower elements (referred to as the “metal remaining gate-last approach” in the following). In the metal remain gate-last approach, it is the poly-Si dummy gate electrodes 5nb and 5pb to be substituted, exhibiting a merit of a simplified process in comparison with other gate-last approaches.

In addition, it is also possible, along with the idea of the original gate-last approach, to remove almost all of the dummy gate stacks 6n and 6p (referred to as “complete gate-last approach” in the following). In the complete gate-last approach, there is a merit of significantly reducing damage to actual gate stacks 6n and 6p by activation heat treatment or the like, as intended by the original gate-last approach.

Furthermore, it is also possible to employ different approaches for the N-type MISFET region Rn and the P-type MISFET region Rp. The metal remaining gate-last approach may be employed for the N-type MISFET region Rn, and the High-k First/Metal Gate Last approach or the complete gate-last approach may be employed for the P-type MISFET region Rp (referred to as “mixed-type gate-last approach”). The mixed-type gate-last approach has a merit that an optimal process can be employed for each of the N-type MISFET region Rn and the P-type MISFET region Rp.

5. Consideration and Supplementary Explanation for the Present Application as a Whole (Including Other Parts) and The Embodiments Thereof.

Each of the embodiments described above improves degradation of the characteristic of the MISFET due to increased film thickness of IL or the like, by performing activation annealing of source/drain, in a state of covering over the device surface 1a of the semiconductor substrate 1 (specifically, at least over the gate structure and its periphery) with the oxygen absorption film 16, and subsequently removing the oxygen absorption film 16. A poly-Si film, an amorphous Si film, an amorphous or poly-SiGe film or the like is representative as the oxygen absorption film 16.

In addition, the oxygen absorption film 16 such as a poly-Si film, an amorphous Si film, an amorphous or poly-SiGe film also exhibits a large SMT effect due to its large structural variation (stress variation) of the film after the high temperature heat treatment such as spike-rapid thermal annealing (Spike-RTA), laser spike annealing (LSA), dynamic surface annealing (DSA) or the like, and therefore the SMT effect can also be shared at the same time, as well as the oxygen absorption effect. There is a case where the oxygen absorption film 16 can be used also as a stress applying film.

Because description of Section 4 of Part 1 is almost directly applicable to this part, the repetitive explanation is omitted below.

6. Summary

The invention made by the inventors has been specifically described above based on embodiments, and the present invention can be modified in various ways within a range not deviating from the spirit.

Although an example using a silicon-based semiconductor film such as an amorphous Si film or a poly-Si film has been specifically described as an oxygen absorption film in the above-mentioned embodiments, the present invention is not limited to it and can be applied to an oxygen absorption film using an SiGe-based semiconductor film, a Ge-based semiconductor film, or the like.

In addition, although description in the above-mentioned embodiments has been provided, mainly taking the gate-last approach as an example, the present invention is not limited to it and can be also applied to the gate-first approach.

What is claimed is:

1. A manufacturing method of a semiconductor integrated circuit device, comprising the steps of (a) patterning an active region by forming an oxide element isolation region over a first main surface of a semiconductor wafer; (b) patterning a High-k gate stack of an N-channel MISFET across the active region over the first main surface of the semiconductor wafer; (c) forming a gate side surface structure on the side surface of the patterned gate stack and then forming a gate structure including the gate stack and the gate side surface structure; (d) forming an impurity-doped region to be source/drain regions of the N-channel MISFET by ion implantation in a semiconductor surface of the active region of the semiconductor wafer on both sides of the gate structure; (e) after the step (d), forming an oxygen absorption film over the first main surface of the semiconductor wafer to cover over the gate structure, over the oxide element isolation region, and over the semiconductor surface; (f) performing activation annealing on the impurity-doped region in a state that the oxygen absorption film covers over the gate structure, over the oxide element isolation region, and over the semiconductor surface; and (g) after the step (f), removing the oxygen absorption film.

2. The manufacturing method of a semiconductor integrated circuit device according to claim 1, wherein the oxygen absorption film is a polysilicon film or an amorphous silicon film.

3. The manufacturing method of a semiconductor integrated circuit device according to claim 2, wherein the semiconductor integrated circuit device is of CMIS type, and the oxygen absorption film does not cover over a P-type MISFET region in the step (f).

4. The manufacturing method of a semiconductor integrated circuit device according to claim 1, wherein the oxygen absorption film is an amorphous or poly-SiGe film.

5. The manufacturing method of a semiconductor integrated circuit device according to claim 2, wherein lanthanum is added to a High-k Gate insulation film constituting the gate stack.

6. The manufacturing method of a semiconductor integrated circuit device according to claim 5, wherein the gate stack is an actual gate stack.

7. The manufacturing method of a semiconductor integrated circuit device according to claim 5, wherein the gate stack is a dummy gate stack.

8. The manufacturing method of a semiconductor integrated circuit device according to claim 6, further comprising the steps of (h) after the step (e) and before the step (f), forming a stress applying film, over the oxygen absorption film, to cover above the gate structure, the oxide element isolation region, and the semiconductor surface; and (i) after the step (f) and before the step (g), removing the stress applying film.

9. The manufacturing method of a semiconductor integrated circuit device according to claim 8, wherein the stress applying film is a silicon nitride-based insulation film.

10. The manufacturing method of a semiconductor integrated circuit device according to claim 9, further comprising the steps of (j) after the step (e) and before the step (h), forming a first silicon oxide-based insulation film on almost entire surface over the oxygen absorption film; and (k) after the step (i) and before the step (g), removing the silicon oxide-based insulation film.

11. The manufacturing method of a semiconductor integrated circuit device according to claim 10, wherein the first silicon oxide-based insulation film is thinner than both the oxygen absorption film and the stress applying film.

12. The manufacturing method of a semiconductor integrated circuit device according to claim 2, wherein a second silicon oxide-based insulation film is interposed between the semiconductor surface and the oxygen absorption film in the formation of the oxygen absorption film in the step (e).
